(19) United States
(12) Patent Application Publication
(10) Pub. No.: US 2026/0103111 A1
(43) Pub. Date: Apr. 16, 2026

(54) METHOD FOR CONTROLLING A BATTERY FOR AN ELECTRIC VEHICLE, AND AN ELECTRIC VEHICLE

(71) Applicants: HYUNDAI MOTOR COMPANY, SEOUL (KR); KIA CORPORATION, SEOUL (KR)

(72) Inventor: Won Jae Lee, Hwaseong-si (KR)

(73) Assignees: HYUNDAI MOTOR COMPANY, SEOUL (KR); KIA CORPORATION, SEOUL (KR)

(21) Appl. No.: 19/228,368

(22) Filed: Jun. 4, 2025

(30) Foreign Application Priority Data
Oct. 16, 2024 (KR) 10-2024-0141665

(51) Int. Cl. B60L 58/12; B60L 58/16; B60L 58/20; B60L 58/22

(52) U.S. Cl. CPC B60L 58/12; B60L 58/16; B60L 58/20; B60L 58/22; B60L 2210/10; B60L 2240/423; B60L 2260/46

(57) ABSTRACT

A method for controlling a battery for an electric vehicle includes: determining one battery among a first battery and a second battery based on an operating area in which an operating characteristic of a driving motor is disposed among a plurality of operating areas for the driving motor by a controller; and controlling power supply for the driving motor or charging by the driving motor using the determined battery by the controller. The controller being configured to determine an adjustment mode for reference data that divide the plurality of operating areas based on SOC and SOH of the first battery and the second battery and perform adjustment for the reference data based on the determined adjustment mode.

### CROSS-REFERENCE TO RELATED APPLICATIONS

The present application claims priority to and the benefit of Korean Patent Application No. 10-2024-0141665, filed on Oct. 16, 2024, the entire contents of which are incorporated herein for all purposes by this reference.

### TECHNICAL FIELD

The present disclosure relates to a method for controlling a battery for an electric vehicle and the electric vehicle.

### BACKGROUND

In general, as wheels of an electric vehicle are driven by a driving force of a driving motor, the electric vehicle travels.

Also, in general, a high-voltage battery is fixedly mounted onto a vehicle to supply power to the driving motor.

The driving motor may be an AC motor, and accordingly, an inverter may be provided between the battery and the driving motor.

The battery of the electric vehicle is charged by receiving external power through an on board charger (OBC) when charging is desired based on a charge state thereof, i.e., state of charge (SoC).

A charging time may be dependent on a charging method which is largely divided into slow charging and fast charging.

In recent years, the continuing research and development on batteries has helped to significantly improve a driving range of a vehicle per charge.

However, a single battery may be still insufficient, and thus, an alternative solution is desired.

### SUMMARY

An embodiment of the present disclosure is provided to relieve or solve the above-described limitations of the related art.

In an electric vehicle using dual batteries, driving on a specific road (e.g., highway) may lead to the predominate use of one battery causing a deviation in state of charge (SOC) between the two batteries. Additionally, external charging may further cause a deviation in SOC and state of health (SOH). Overtime, these imbalances may cause a deviation in the durability of the batteries in a long-term perspective. The present disclosure is intended to relieve the above-described limitations.

The present disclosure provides an efficient operational strategy for dual batteries based on a plurality of operating areas that are distinguished in consideration of SOHs of the dual batteries and an operating characteristic of a driving motor.

The present disclosure also provides a technology having a new concept of using a second high-voltage battery capable of being added to or separated from a power system of an electric vehicle as necessary in addition to a first high-voltage battery installed in advance on the electric vehicle.

An embodiment of the present disclosure provides a method for controlling batteries for an electric vehicle. The method includes: determining, by a controller, a battery between one of a first battery and a second battery based on an operating area in which an operating characteristic of a driving motor is disposed among a plurality of operating areas; and controlling, by the controller, power supply from the determined battery to the driving motor and/or charging the determined battery by power generated by the driving motor. The determining between one of the first battery and the second battery includes: determining, by the controller, an adjustment mode for reference data that divide the plurality of operating areas based on states of charge (SOCs) and states of health (SOHs) of the first battery and the second battery; and adjusting, by the controller, the reference data based on the determined adjustment mode

In an embodiment, the adjustment mode includes a SOC-based adjustment, a SOH-based adjustment, and a SOC/SOH-based adjustment.

In an embodiment, the determining the adjustment mode includes at least one of: determining the SOC-based adjustment as the adjustment mode when an SOC of at least one battery of the first battery and the second battery is deviated from a set SOC range; and determining the SOC/SOH-based adjustment as the adjustment mode when both SOCs of the first battery and the second battery are within the set SOC range. The determining the adjustment mode further includes determining the SOH-based adjustment as the adjustment mode when both the SOCs of the first battery and the second battery are within the set SOC range, a difference between the SOCs of the first battery and the second battery is less than a set SOC difference, and a difference between SOHs of the first battery and the second battery is deviated from a set SOH range.

In an embodiment, the SOC-based adjustment includes adjusting the reference data based on the SOCs of the first battery and the second battery.

In an embodiment, the SOC-based adjustment includes: a first SOC-based adjustment of adjusting the reference data based on a first mode oriented towards charging a lower-voltage battery and/or discharging a higher-voltage battery when a first SOC of the lower-voltage battery among the first battery and the second battery is less than a second SOC of the higher-voltage battery among the first battery and the second battery; and/or a second SOC-based adjustment of adjusting the reference data based on a second mode oriented towards discharging the lower-voltage battery and/or charging the higher-voltage battery when the first SOC is greater than the second SOC.

In an embodiment, the first SOC-based adjustment includes adjusting the reference data to extend a higher-voltage discharging area and/or a lower-voltage charging area of the plurality of operating areas. The second SOC-based adjustment includes adjusting the reference data to extend a lower-voltage discharging area and/or a higher-voltage charging area of the plurality of operating areas.

In an embodiment, the reference data includes at least one hysteresis of: power-based hysteresis; torque-based hysteresis; or revolutions per minute (RPM)-based hysteresis. The adjusting the reference data includes adjusting the at least one hysteresis.

In an embodiment, the at least one hysteresis is determined based on an average and a standard deviation obtained based on learning data.

In an embodiment, the adjusting the at least one hysteresis includes adjusting the at least one hysteresis by an adjustment amount determined based on the standard deviation.

In an embodiment, the adjustment amount is determined based on a difference between the first SOC and the second SOC and the standard deviation.

In an embodiment, the SOH-based adjustment includes adjusting the reference data based on the SOHs of the first battery and the second battery.

In an embodiment, the SOH-based adjustment includes: a first SOH-based adjustment of adjusting the reference data to increase use of a higher-voltage battery among the first battery and the second battery and to decrease use of a lower-voltage battery among the first battery and the second battery when a first SOH of the lower-voltage is less than a second SOH of the higher-voltage battery; and/or a second SOH-based adjustment of adjusting the reference data to increase the use of the lower-voltage battery and to decrease the use of the higher-voltage battery when the first SOH is greater than the second SOH.

In an embodiment, the first SOH-based adjustment includes adjusting the reference data to extend a higher-voltage discharging area and/or a lower-voltage charging area of the plurality of operating areas. The second SOH-based adjustment includes adjusting the reference data to extend a lower-voltage discharging area and/or a higher-voltage charging area of the plurality of operating areas.

In an embodiment, the reference data includes at least one hysteresis of: power-based hysteresis: torque-based hysteresis: or revolutions per minute (RPM)-based hysteresis, and the adjusting of the reference data includes adjusting the at least one hysteresis.

In an embodiment, the at least one hysteresis is determined based on an average and a standard deviation obtained through learning.

In an embodiment, the adjusting of the at least one hysteresis includes adjusting the at least one hysteresis by an adjustment amount determined based on the standard deviation.

In an embodiment, the adjustment amount is determine based on a difference between the first SOH and the second SOH and the standard deviation.

In an embodiment, the SOC/SOH-based adjustment includes: determining a first adjustment amount to change the reference data based on the SOCs of the first battery and the second battery; and determining a second adjustment amount to change the reference data based on the SOHs of the first battery and the second battery.

In an embodiment, the SOC/SOH-based adjustment further includes determining a total adjustment amount by addition or multiplication of the first adjustment amount and the second adjustment amount.

In an embodiment of the present disclosure, an electric vehicle includes: a plurality of wheels; a driving motor configured to supply driving force to the plurality of wheels; and a controller configured to control power supply for the driving motor using a first battery or a second battery and/or charging the first battery or the second battery by power generated by the driving motor. The controller includes a non-transitory memory storing computer-readable instructions and at least one processor configured to execute the computer-readable instructions. The computer-readable instructions, when executed by the at least one processor, causes the controller to determine a battery between one of the first battery and the second battery based on an operating area in which an operating characteristic of the driving motor is disposed among a plurality of operating areas. The computer-readable instructions, when executed by the at least one processor, further cause the controller to: control power supply from the determined battery to the driving motor and/or charging the determined battery by power generated by the driving motor; determine an adjustment mode for reference data that divide the plurality of operating areas based on states of charge (SOCs) and states of health (SOHs) of the first battery and the second battery; and adjust the reference data based on the determined adjustment mode.

### BRIEF DESCRIPTION OF THE DRAWINGS

FIG. 1 illustrates a power system of a first mobility according to an embodiment of the present disclosure.

FIG. 2 illustrates a state in which a first mobility is connected to a second mobility according to an embodiment of the present disclosure.

FIGS. 3, 4, and S are flowcharts illustrating a control process according to an embodiment of the present disclosure.

FIG. 6 is a table illustrating specifications of a first high-voltage battery and a second high-voltage battery.

FIG. 7 illustrates a plurality of operating areas on a torque-revolutions per minute (RPM) map.

FIG. 8 illustrates an equivalent output reference line, an equivalent accelerator pedal signal (APS) reference line, and a revolutions per minute (RPM) reference line based on learning data.

FIG. 9 is a flowchart illustrating a process of acquiring learning data.

FIGS. 10-12 are tables illustrating data obtained in the process of acquiring learning data.

FIG. 13 illustrates an example of assuming a control simulation according to an embodiment of the present disclosure.

FIG. 14 illustrates an adjustment of reference data according to an embodiment of the present disclosure.

FIG. 15 illustrates an adjustment of reference data according to another embodiment of the present disclosure.

FIG. 16 is a flowchart illustrating a hysteresis adjustment process according to an embodiment of the present disclosure.

FIG. 17 is a flowchart illustrating a hysteresis adjustment process according to another embodiment of the present disclosure.

FIG. 18 conceptually illustrates states of health (SOHs) of dual-batteries for assumed driving conditions according to an embodiment of the present disclosure.

FIGS. 19A and 19B illustrate an example of outputting a hysteresis adjustment on an instrument cluster according to another embodiment of the present disclosure.

FIG. 20 is a flowchart illustrating a hysteresis adjustment process according to an embodiment of the present disclosure.

FIG. 21 is a flowchart illustrating a hysteresis adjustment process according to another embodiment of the present disclosure.

FIG. 22 is a flowchart illustrating a hysteresis adjustment process according to an embodiment of the present disclosure.

FIG. 23 is a flowchart illustrating a hysteresis adjustment process according to another embodiment of the present disclosure.

FIG. 24 is a conceptual view illustrating SOHs of dual-batteries for assumed driving conditions according to an embodiment of the present disclosure.

FIGS. 25A and B illustrate an example of outputting a hysteresis adjustment on an instrument cluster according to another embodiment of the present disclosure.

FIG. 26 is a block diagram illustrating a method for manufacturing a hinge in stages according to an embodiment of the present disclosure.

FIG. 27 is a conceptual view illustrating SOHs of dual-batteries for assumed driving conditions according to an embodiment of the present disclosure.

### DETAILED DESCRIPTION

Since the present disclosure may have diverse modified embodiments, example embodiments are illustrated in the drawings and are described in the detailed description of the present disclosure. However, this does not limit the present disclosure within the specific embodiments and it should be understood that the present disclosure covers all the modifications, equivalents, and replacements within the idea and technical scope of the present disclosure.

In this specification, the suffixes “module” and “unit” are used merely for nominal distinction between components and should not be interpreted as implying that the components are physically or chemically separated or that they can be separated.

It should be understood that although the terms of “first” and “second” are used herein to describe various elements, these elements should not be limited by these terms. These terms may be used solely to differentiate one component from another in name, and their sequential meanings are understood through the context of the description rather than by the names themselves.

The term “and/or” is used to include all possible combinations of the listed items. For example, “A and/or B” includes all three cases of “A”, “B”, and “A and B”.

It should also be understood that when an element is referred to as being “connected to” or “engaged with” another element, it can be directly connected to the other element, or intervening elements may also be present.

In the following description, the technical terms are used only for explaining a specific embodiment while not limiting the present disclosure. The terms of a singular form may include plural forms unless referred to the contrary. The meaning of ‘include’ or ‘comprise’ specifies a property, a region, a fixed number, a step, a process, an element and/or a component but does not exclude other properties, regions, fixed numbers, steps, processes, elements and/or components.

Unless otherwise defined in the present disclosure, the terms should be interpreted according to their commonly understood meanings by those having ordinary skill in the art. Terms that are generally used and have been found in dictionaries should be construed as having meanings consistent with contextual meanings in the art. In this description, unless defined clearly, terms are not ideally, excessively construed as formal meanings.

Also, terms such as unit, control unit, control device, or controller are widely used to name devices that control specific functions and do not refer to a generic functional unit. Also, the devices denoted by the names may include a communication device that communicates with another controller or sensor to control the corresponding function, a computer-readable recording medium that stores an operating system, a logic command, and input/output information, and at least one processor that performs determinations, decisions, and calculations desired for function control.

On the other hand, the processor may include semiconductor integrated circuits and/or electronic elements that perform at least one or more of comparisons, determinations, calculations, and decisions to achieve programmed functions. For example, the processor may be a computer, a microprocessor, CPU, ASIC, an electronic circuitry (logic circuits), or a combination thereof.

When a controller, component, device, element, part, unit, module, or the like of the present disclosure is described as having a purpose or performing an operating, function, or the like, the controller, component, device, element, part, unit, or module should be considered herein as being “configured to” meet that purpose or perform that operating or function. Each controller, component, device, element, part, unit, module, and the like may separately embody or be included with a processor and a memory, such as a non-transitory computer-readable media, as part of the apparatus.

Also, the computer readable recording medium (or memory) includes all sorts of data storage devices that store computer readable data. For example, the computer readable recording medium may include at least one of a flash memory type, hard disk type, micro type, card type (e.g., secure digital (SD) card) or eXtream digital (XD) type memory and a random access memory (RAM), static RAM (SRAM), read-only memory (ROM), programmable ROM (PROM), electrically erasable PROM (EEPROM), magnetic RAM (MRAM), magnetic disk, or optical disk type memory.

These recording media may be electrically connected to the processor, and the processor may read data from and write data to the recording media. The recording media and the processor may be integrated with each other or physically separated from each other.

Hereinafter, the accompanying drawings are briefly described, and embodiments of the present disclosure are described in detail with reference to the drawings.

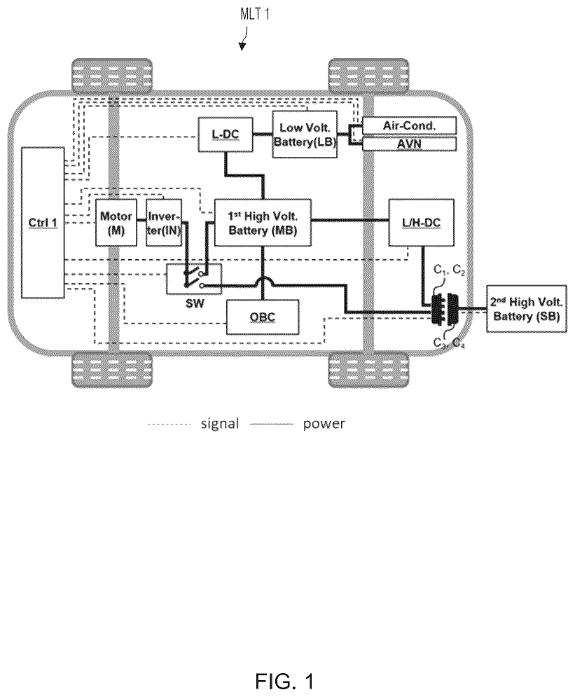

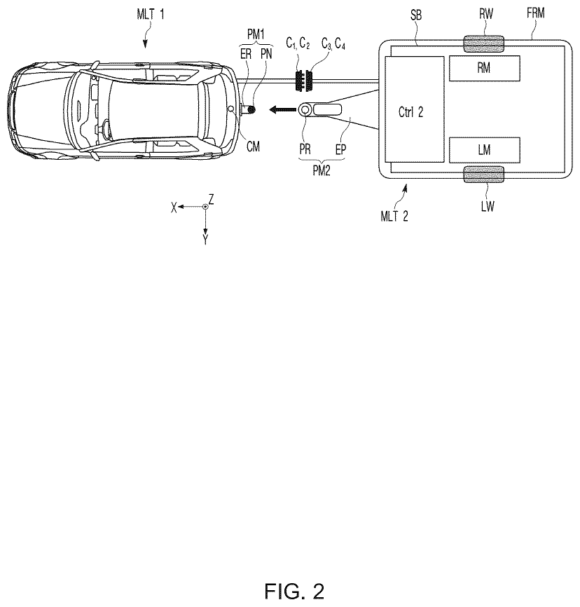

FIG. 1 is a conceptual view illustrating a power system of a first mobility MLT1 (e.g., electric vehicle) according to an embodiment of the present disclosure. FIG. 2 is a view illustrating a state in which a second mobility MLT2 is connected to the first mobility MLT1.

A structure of each of the first mobility MLT1 and the second mobility MLT 2 according to an embodiment of the present disclosure are described with reference to FIGS. 1 and 2.

As illustrated in FIG. 1, the first mobility MLT1 according to an embodiment of the present disclosure is, e.g., an electric vehicle, and includes a first driving motor M, an inverter IN, a first high-voltage battery MB, an on-board charger OBC, a first DC/DC converter L-DC, a low-voltage battery LB, a low-voltage air-conditioner Air-cond, an audio video navigation (AVN) that operates at a low-voltage, a second DC/DC converter L/H-DC, a switch SW, and a controller (hereinafter, referred to as a first controller).

The first driving motor M provides driving force to the wheels of the vehicle. For example, the first driving motor M may be an alternating current motor.

The inverter IN converts direct current power supplied to the first driving motor M into alternating current.

The first high-voltage battery MB may be fixedly mounted to a body, e.g., under a floor of a cabin, of the first mobility MLT1.

The first high-voltage battery MB may have a main function of supplying electric power to the first driving motor M and charged by the on-board charger OBC.

Also, the first high-voltage battery MB may be connected to the low-voltage battery LB through the first DC/DC converter L-DC to charge the low-voltage battery LB.

The first DC/DC converter L-DC may be a low-voltage DC-DC converter LDC in order to charge the low-voltage battery LB.

For example, the low-voltage battery LB may be a 12 V or 24 V battery. The low-voltage battery LB supplies electric power to an electrical device in the vehicle, such as an air conditioner or AVN that operates at a low voltage.

Although the second high-voltage battery SB is installed in the second mobility MLT2 and mechanically connected through a connection mechanism, which is described below, as illustrated in FIG. 1, the embodiment of the present disclosure is not limited thereto. For example, the second high-voltage battery SB may be detachably installed and mechanically connected to the first mobility.

The second high-voltage battery SB may be electrically connected additionally to a vehicle power system including the first high-voltage battery MB, i.e., in a separately wired method (or a wireless method within an allowable range) that has no effect on an operation (power supply to electronic components of the vehicle and the driving motor) of the power system.

Also, although the second high-voltage battery SB may be referred to as a replaceable battery, auxiliary battery, extended battery, second or secondary battery, this is merely for differentiating from the first high-voltage battery MB. In other words, all sorts of features of the second high-voltage battery SB, such as a function, characteristics, a mechanical/electrical/chemical structure based on a relationship with other objects (including the first high-voltage battery MB and a host vehicle), a battery type (including the kinds of packaging method, positive electrode material/negative electrode material/separation membrane material), and a charging method, are not limited by a name of the second high-voltage battery SB.

The second high-voltage battery SB may be connected to a first controller Ctrl 1 of the first mobility MLT1 or a battery management system (BMS) of the first high-voltage battery MB, which is further described below, in a wired or wireless manner. Through this, all sorts of sensing information (e.g. voltage, current, temperature, and the like) related to a state of charge (SoC) state and a physical/electrical/chemical state of the second high voltage battery SB is transmitted to the first controller Ctrl 1. However, the embodiment of the present disclosure is not limited thereto. For example, the above-described information related to the second high-voltage battery SB may be transmitted to the first controller Ctrl 1 through a second controller Ctrl 2 of the second mobility MLT 2, which is further described below.

In this embodiment, a high-voltage battery applied to the first high-voltage battery MB and the second high-voltage battery SB may include a plurality of battery cells (not shown) that output a voltage of, e.g., 2.7 V to 4.2 V. The number of the plurality of battery cells to be connected in series or parallel may be set, so that the plurality of battery cells form one module. The high-voltage battery may be packaged such that one or more battery modules are connected in series or parallel as one battery to output, e.g., about 400 V, about 800 V, or several kV.

Each of the first high-voltage battery MB and the second high-voltage battery SB may include a battery management system (BMS).

The BMS may include a battery management unit (BMU), a cell monitoring unit (CMU), and a battery junction box (BJB).

The BMS performs a cell balancing function of maintaining a voltage of each of the cells at a constant level to secure a performance of an entire battery pack, a state of charge (SoC) function of calculating a capacity of an entire battery system, a state of health (SOH) calculation, battery cooling, charging, and discharging control.

The BMU receives information on all cells from the CMU and performs the functions of the BMS based on the received information.

The BMU may include, e.g., two micro control units (MCU), and each of the MCUs may have one CAN communication port. The BMU may further include a CAN interface to communicate with a vehicle controller that is a device at an upper hierarchy level of the BMS and a CAN interface to collect information from the CMU that is a device at a lower hierarchy level of the BMS.

The CMU may be attached directly to the battery cell to sense a voltage, a current, and a temperature. The CMU may serve to perform sensing only instead of performing a calculation related to a BMS algorithm. One CMU may be formed by connecting a plurality of battery cells and transmit information of each of the cells to the BMU through the CAN interface.

The BJB is a pack-level sensing mechanism of the BMS and a connection medium between the high-voltage battery and a drivetrain. For accurately calculating the SoC, a battery voltage and a current flowing into and out of the battery are measured and recorded. Also, the BJB may perform an important function in safety, such as insulation monitoring in addition to overcurrent detection.

The second high-voltage battery SB may be a high-voltage battery having a voltage less than that of the first high-voltage battery MB. In this case, the second DC/DC converter L/H-DC may be a step-up DC/DC converter. On the contrary, the second high-voltage battery SB may be a high-voltage battery having a voltage greater than that of the first high-voltage battery MB. In this case, the second DC/DC converter L/H-DC may be a step-down DC/DC converter. Also, in this embodiment, the second DC/DC converter L/H-DC may be a bidirectional converter, and thus, the first high-voltage battery MB and the second high-voltage battery SB may charge and discharge each other.

In this embodiment, although the second DC/DC converter L/H-DC is included as a built-in component of the first mobility MLT1 in the power system, the embodiment of the present disclosure is not limited thereto. For example, unlike this embodiment, the second DC/DC converter L/H-DC may be provided as a separate component and additionally detachably connected to the power system. Also, the second DC/DC converter L/H-DC may be built-in or detachably included in the second mobility MLT 2.

Also, unlike the present embodiment, the second DC/DC converter L/H-DC may not be included in other embodiments. In this case, charging and discharging between the first high-voltage battery MB and the second high-voltage battery SB do not occur.

In this embodiment, the power system of the first mobility MLT1 may include first and second connectors C1 and C2, and the second high-voltage battery SB may include third and fourth connectors C3 and C4 for a separable electrical connection to the power system of the second high-voltage battery SB.

For example, each of the first and second connectors C1 and C2 may be an integrated connector, and each of the third and fourth connectors C3 and C4 may be also an integrated connector.

The first connector C1 may be connected to the second DC/DC converter L/H-DC, and the second connector C2 may be connected to the switch SW.

Although not shown, a signal transmission connector may be added to transmit all sorts of sensing and state information of the second high-voltage battery SB to the controller.

The switch SW is fixedly electrically connected to the inverter IN and switched between the first high-voltage battery MB and the second connector C2 to electrically connect the inverter IN and the first high-voltage battery MB and/or the inverter IN and the second high-voltage battery SB.

In this embodiment, although the first controller Ctrl 1 may be a vehicle controller at an uppermost hierarchy level, which controls all electric devices of the first mobility MLT1, the embodiment of the present disclosure is not limited thereto. In other words, for example, the first controller Ctrl 1 in FIG. 1 may be a power controller at a lower hierarchy level of the vehicle controller.

Also, in this embodiment, as described above, the first controller Ctrl 1 may include a computer-readable recording medium that stores an operating system, a logic command, and input/output information, and at least one processor that reads the above-described stored system, command, and information to perform a decision or calculation required for function control.

The second high-voltage battery SB in FIG. 1 may be installed in the second mobility MLT 2 as illustrated in FIG. 2.

The second mobility MLT 2 includes a frame FRM, a second left wheel LW disposed at a left side of the frame FRM, a second right wheel RW disposed at a right side of the frame FRM, a second left driving motor LM providing driving force to the second left wheel LW, a second right driving motor RM providing driving force to the second right wheel RW, and a second controller Ctrl 2.

Although the second high-voltage battery SB may be fixedly installed on the second mobility MLT 2, the embodiment of the present disclosure is not limited thereto. In other words, the second high-voltage battery SB may be detachably installed on the second mobility MLT 2. Through this, the second high-voltage battery SB in a completely discharged SoC state, which is mounted to the frame FRM, may be removed and replaced with a new second high-voltage battery SB in a fully charged SoC state.

When the second high-voltage battery SB is fixedly installed on the second mobility MLT 2, the second mobility MLT 2 may include a charging connector for charging the second high-voltage battery SB.

The frame FRM forms an appearance of the second mobility MLT 2 and serves to accommodate other components.

The frame FRM may include a second pivot mechanism PM2 that is a second connection mechanism. The second pivot mechanism PM2 may be separably pivot-connected to a first pivot mechanism PM1 that is a first connection mechanism fixed to a body of the first mobility MLT1.

For example, the first pivot mechanism PM1 includes an extension rod ER extending rearward from the body of the first mobility MLT1 and a pivot pin PN protruding upward from an end of the extension rod ER.

Also, the second pivot mechanism PM2 includes an extension part EP having a triangular shape protruding forward from the frame FRM of the second mobility MLT 2 and a pivot ring PR that is disposed at an end of the extension part EP and to which the pivot pin PN is rotatably inserted.

The pivot pin PN may perform a restricted linear movement in a state of being inserted to the pivot ring PR and only perform a rotation in a Z-axis direction of FIG. 2. Thus, in the pivot-connected state, the second mobility MLT2 may be restricted in linear movement using a pivot connection point as a center with respect to the first mobility MLT1 and only rotate about a Z axis.

When the second mobility MLT2 travels in a forward direction, i.e., an X-axis direction, each of the first mobility MLT1 and the second mobility MLT2 may maintain straightness thereof without separate steering control.

Although the pivot mechanism is included as the first and second connection mechanisms in this embodiment, the embodiment of the present disclosure is not limited thereto. For example, the first and second connection mechanisms may be well-known mechanisms that realize non-rotational connection about the Z-axis.

The second left driving motor LM has a rotation shaft that is connected to the second left wheel LW, and through this, the second left driving motor LM provides driving force to the second left wheel LW.

Also, the second right driving motor RM has a rotation shaft that is connected to the second right wheel RW, and through this, the second right driving motor RM provides driving force to the second right wheel RW.

Since the second left wheel LW and the second right wheel RW are connected to the second left driving motor LM and the second right driving motor RM, respectively, the second left wheel LW and the second right wheel RW may be driven independently from each other.

Since each of the second left driving motor LM and the second right driving motor RM may be driven in forward and backward directions, when driven in the forward direction, the second mobility MLT 2 travels forward, and when driven in the backward direction, the second mobility MLT 2 travels backward.

For example, although each of the second left driving motor LM and the second right driving motor RM may be realized as an in-wheel driving system in which each driving motor is installed in each wheel, the embodiment of the present disclosure is not limited thereto.

Also, unlike this embodiment, the second mobility MLT 2 may be driven in such a manner that power of one common motor is distributed to the second left wheel LW and the second right wheel RW instead of independent driving of the left and right wheels. To this end, a differential gear may be included between the common second driving motor and the second left and right wheels LW and RW. In other words, the power of the common second driving motor may be distributed by the differential gear and transmitted to the second left wheel LW and the second right wheel RW. In this case, a torque vectoring unit may be added for torque distribution between the second left wheel LW and the second right wheel RW.

In FIG. 2, the second controller Ctrl 2 controls the second left driving motor LM and the second right driving motor RM to perform forward and reverse traveling of the second mobility MLT 2. Also, when steering of the second mobility MLT 2 is required, the second controller Ctrl 2 may change a traveling direction of the second mobility MLT2 through controlling a torque or the number of rotation of each of the second left driving motor LM and the second right driving motor RM. In other words, the steering of the second mobility MLT 2 may be performed without a separate steering device through independent control of the driving of the second left driving motor LM and the second right driving motor RM.

Also, as described above, the connectors and the wired or wireless communication units for transmitting information between the first mobility MLT1 and the second mobility MLT2 in FIG. 1 are included.

In this embodiment, each of the first controller Ctrl 1 and/or the second controller Ctrl 2 may include a memory and a processor. The memory stores computer commands (programs) for performing functions of the corresponding controller, and the processor performs the above-described functions by reading and executing the commands from the memory.

For example, the memory includes at least one of a hard disk drive (HDD), a solid-state drive (SDD), a silicon disk drive (SDD), ROM, RAM, CD-ROM, a magnetic tape, a floppy disk, and an optical data storage device.

Also, for example, the processor includes at least one of a computer, a microprocessor, a central processing unit (CPU), an ASIC, an electric circuit, and a logic circuit.

As the first connector C1 and the second connector C2 of the first mobility MLT 1 and the third connector C3 and the fourth connector C4 of the second mobility MLT 2 are connected, and the connector for signal transmission is connected, the first mobility MLT 1 and the second mobility MLT 2, i.e., the first controller Ctrl 1 and the second controller Ctrl 2, may communicate with each other.

When the first mobility MLT 1 initiates to travel forward in a state in which the first mobility MLT 1 and the second mobility MLT 2 are mechanically and electrically connected, based on a traveling speed signal transmitted from the first connector C1, the second controller Ctrl 2 controls the second left driving motor LM and the second right driving motor RM to perform a forward straight traveling of the second mobility MLT 2.

Some or all of a speed, a gear position, a steering angle, accelerator pedal sensor (APS) information, and brake pedal sensor (BPS) information of the first mobility MLT 1 may be transmitted to the second mobility MLT 2.

The second controller Ctrl 2 of the second mobility MLT 2 may determine whether the first mobility MLT 1 is in a forward traveling state or a backward traveling state by using, e.g., some or all of the speed, the gear position, the APS information, and the BPS information of the first mobility MLT 1. However, the embodiment of the present disclosure is not limited thereto. For example, the second controller Ctrl 2 may directly receive information on whether the first mobility MLT 1 is in the forward traveling state or the backward traveling state from the first controller Ctrl 1.

When the first mobility MLT1 travels forward, the second controller Ctrl 2 drives the second left driving motor LM and the second right driving motor RM in the forward direction to perform the forward traveling of the second mobility MLT 2. When the first mobility MLT1 travels backward, the second controller Ctrl 2 drives the second left driving motor LM and the second right driving motor RM in the back ward direction to perform the backward traveling of the second mobility MLT 2.

Also, the second controller Ctrl 2 may determine a steering state through steering angle information of the first mobility MLT 1 and perform steering of the second mobility MLT 2 based on the determined steering state.

The second mobility MLT 2 may not include a separate steering device such as a steering wheel and a steering rack and perform the steering through torque control of the second left driving motor LM and the second right driving motor RM.

In other words, the second controller Ctrl 2 may calculate traveling torque for traveling and steering torque for steering for each of the second left driving motor LM and the second right driving motor RM and use the calculated torque for control.

For example, a lookup table or calculation program may include steering torque values of the second left driving motor LM and the second right driving motor RM based on the steering angle of the first mobility MLT 1 to perform steering of the second mobility MLT 2.

During the forward straight traveling, the second mobility MLT 2 may be controlled to travel at a speed equal to or less than that of the first mobility MLT 1. Through this, the pivot connection between the first mobility MLT 1 and the second mobility MLT 2 may be maintained within a predetermined pivot angle range. For example, when a speed of the second mobility MLT 2 is controlled to be equal to or less than that of the first mobility MLT 1 during the forward straight traveling, a pivot angle of the second mobility MLT2 with respect to the first mobility MLT 1 at a pivot connection point may maintain 0° (which represents an angle at which the first mobility MLT 1 and the second mobility MLT 2 are on a straight line).

During the forward straight traveling, the second mobility MLT 2 may be controlled to follow the first mobility MLT 1, and through this, a plurality of mobilities may be smoothly connected to travel.

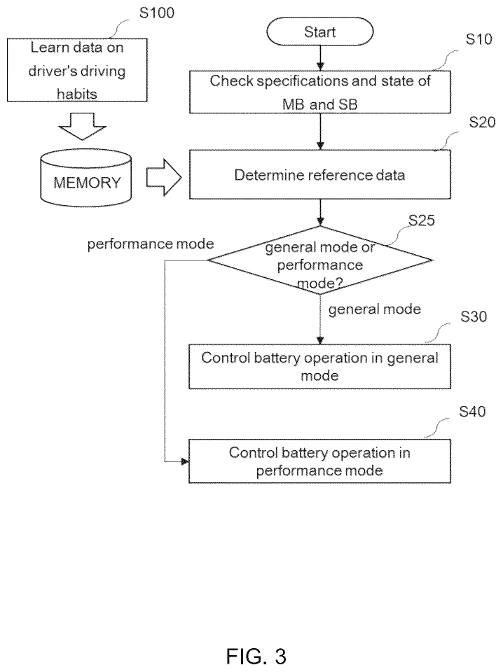

FIG. 3 is a flowchart illustrating a control process according to an embodiment of the present disclosure, which is described in detail below.

Although a control process of the battery is performed under control of the first controller Ctrl 1 in this embodiment, the embodiment of the present disclosure is not limited thereto.

The first controller Ctrl 1 includes a memory and a processor as described above. The memory stores a computer program for battery usage control according to the embodiment and, as necessary, various data required for the control process. The processor executes the program stored in the memory, and through this, the first controller Ctrl 1 performs battery usage control based on the program.

Referring to FIG. 3, in step S10, the first controller Ctrl 1 checks specifications and a state of the first high-voltage battery MB and/or the second high-voltage battery SB.

The specifications may include at least one of C-rate, nominal voltage, efficiency, maximum current, system voltage, and a continuous output, and the state of the battery may include at least one of SOH, SOC, voltage, and temperature.

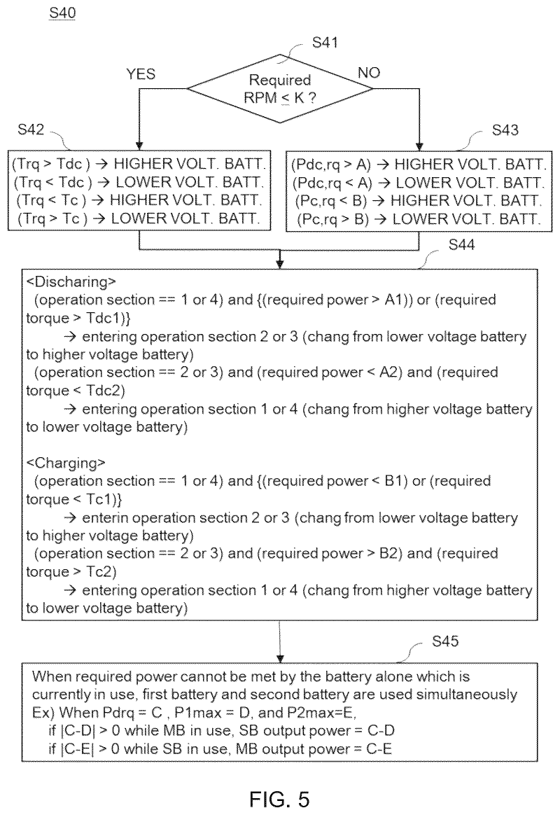

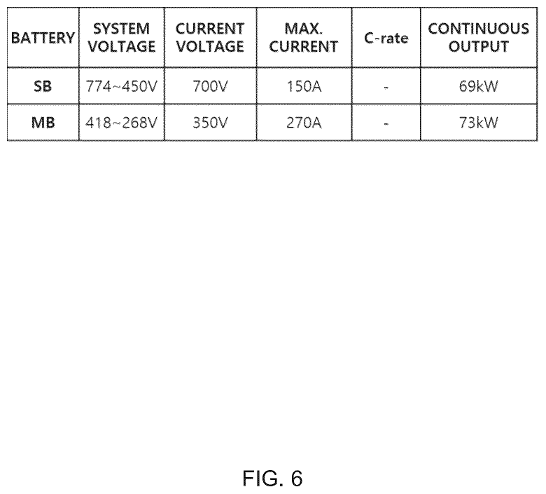

FIG. 6 is a table illustrating the specifications of the first high-voltage battery MB and the second high-voltage battery SB.

Hereinafter, as illustrated in FIG. 6, although the first high-voltage battery MB has a voltage less than that of the second high-voltage battery SB as an example, the embodiment of the present disclosure is not limited thereto.

The first controller Ctrl 1 may determine that the first high-voltage battery MB is a lower-voltage battery based on the specifications of the first high-voltage battery MB and the second high-voltage battery SB.

Thereafter, in step S20, the first controller Ctrl 1 determines reference data (e.g., criteria data).

The reference data is used to distinguish (e.g., divide) a plurality of operating areas (e.g., operating regions) that are described below, and includes learning data obtained through learning on driving habits of drivers.

When the learning data is not obtained yet or the driver chooses not to use the learning data even when the learning data is obtained, the system may determine the corresponding data, which is described below. Additionally, the learning data is described below.

First, the first controller Ctrl 1 may determine a high-efficiency output power, an accelerator pedal sensor (APS) converted value, and a reference revolutions per minute (RPM) for the lower-voltage battery, i.e., the first high-voltage battery MB, among the first high-voltage battery MB and the second high-voltage battery SB.

For example, the memory may store high-efficiency output data for each specification of the battery, and the first controller Ctrl 1 may select data matched with the specifications of the first high-voltage battery MB among the output data and determine the high-efficiency output power.

In other words, the first controller Ctrl 1 determines high-efficiency discharge power A and charge power B of a static power range of the first high-voltage battery MB.

Thereafter, the first controller Ctrl 1 may determine APS converted values for the high-efficiency output power A and B. Torque may be determined based on the APS converted values, and accordingly, an equivalent APS reference line may serve as an equivalent torque reference line of the corresponding torque.

For example, a required APS value that is determined by a degree to which the driver presses an accelerator pedal may be converted into a required output of the first driving motor M through an equation that is set in advance and stored in the memory, and the first controller Ctrl 1 may convert the high-efficiency output into the APS value by using this equation.

Also, the first controller Ctrl 1 may determine a reference RPM (K) for an RPM reference line that is described below based on a torque-RPM map for the first driving motor M.

For example, in the torque-RPM map, an RPM at an intersection point of a maximum torque line Tq,max and the maximum output line Pwr,max of the driving motor M may be determined as a reference RPM K.

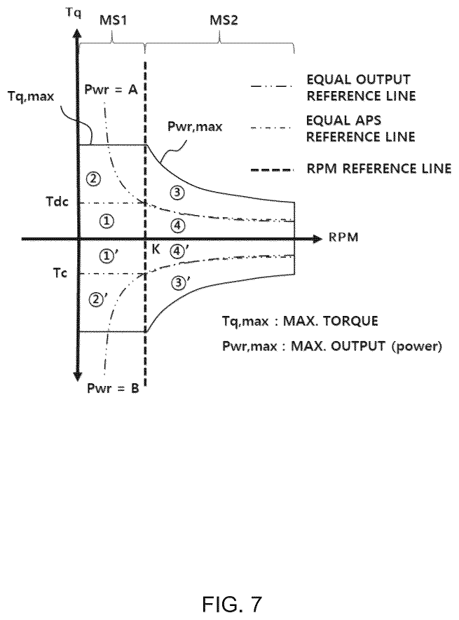

For example, in the torque-RPM map shown in FIG. 7, an RPM at the intersection point of the maximum torque line Tq=Tq,max, and the maximum output line Pwr=Pwr,max may be determined as the reference RPM (K).

Also, the first controller Ctrl 1 may determine discharge torque Tdc and charge torque Tc for a constant torque period based on the equation below.

$$\begin{matrix}Tdc = A / K \\ Tc = B / K\end{matrix} \qquad [ Mathematical equation 1 ]$$

The reference data may include the high-efficiency output power A and B and the reference RPM (K), and a plurality of operating areas may be classified by the reference data.

As illustrated in FIG. 7, the plurality of operating areas are divided (e.g., classified) into a first discharging operating area (1), a second discharging operating area (2), a third discharging operating area (3), and a fourth discharging operating area (4) by an equivalent output reference line, an equivalent APS reference line, and an RPM reference line, based on a driving condition, i.e., a discharge condition of the battery.

The equivalent output reference line is an equivalent output line on the torque-RPM map for the above-described high-efficiency output of the first high-voltage battery MB.

Also, the equivalent APS reference line is an equivalent APS line for APS values converted in accordance with the high-efficiency output.

Also, the RPM reference line corresponds to the above-described reference RPM line. In this embodiment, the reference RPM is a boundary between the equivalent torque period and the equivalent output period in the map of FIG. 5.

Referring to FIG. 7, the first discharging operating area (1) corresponds to an area below the RPM reference line and the equivalent APS ‘Tq=Tdc’ reference line. The second discharging operating area (2) corresponds to an area surrounded by the equivalent output ‘Pwr=A’ reference line, the equivalent APS ‘Tq=Tdc’ reference line, and the predetermined maximum discharge torque line (‘Tq=Tq,max’). The third discharging operating area (3) is determined as an area exceeding the equivalent output ‘Pwr=A’ reference line. The fourth discharging operating area (4) is determined as an area exceeding the RPM reference line but below the equivalent output ‘Pwr=A’ reference line.

Also, in FIG. 7, a torque area below 0 (zero) may correspond to a regenerative braking condition caused by the first driving motor M, i.e., a battery charge condition, and may be distinguished, in the same manner, into four operating areas based on the equivalent output reference line, the equivalent APS reference line, and the RPM reference line. In other words, as illustrated in FIG. 7, for the charge condition, the first charging operating area (1)′ corresponds to an area below the RPM reference line and above the equivalent APS ‘Tq=Tc’ reference line. The second charging operating area (2)′ corresponds to an area surrounded by the equivalent output ‘Pwr=B’ reference line, the equivalent APS ‘Tq=Tc’ reference line, and the predefined maximum charge torque line (‘Tq=−Tq,max’). The third charging operating area (3)′ is determined as an area below the equivalent output ‘Pwr=B’ reference line, and the fourth charging operating area (4)′ is determined as an area exceeding the RPM reference line and above the equivalent output ‘Pwr=B’ reference line.

In FIG. 7, division of the operating areas in a driving condition by the first driving motor M and division of the operating areas in a regenerative braking condition may be symmetric with each other based on the RPM axis.

When the driving mode is a general mode that is described below, as in step S31, the first high-voltage battery MB using a lower voltage is used in the first discharging operating area (1) and the second discharging operating area (2), and the second high-voltage battery SB using a higher voltage is used in the third discharging operating area (3) and the fourth discharging operating area (4). In other words, in the general mode, each of the first discharging operating area (1) and the second discharging operating area (2) corresponds to a low-voltage discharge area, and each of the third discharging operating area (3) and the fourth discharging operating area (4) corresponds to a higher-voltage discharge area.

In the regenerative braking condition during the general mode, the first high-voltage battery MB using the lower voltage is used in the first charging operating area (1)′ and the second charging operating area (2)′, and the second high-voltage battery SB using the high voltage is used in the third charging operating area (3)′ and the fourth charging operating area (4)′. In other words, in the general mode, each of the first charging operating area (1)′ and the second charging operating area (2)′ corresponds to a low-voltage charging area, and each of the third charging operating area (3)′ and the fourth charging operating area (4)′ corresponds to a higher-voltage charging area.

Also, when the driving mode is a performance mode, as in steps S41 to S43 described below, the first high-voltage battery MB using the lower voltage is used in the first discharging operating area (1) and the fourth discharging operating area (4), and the second high-voltage battery SB using the higher voltage is used in the second discharging operating area (2) and the third discharging operating area (3). In other words, in the performance mode, each of the first discharging operating area (1) and the fourth discharging operating area (4) corresponds to the low-voltage discharge area, and each of the second discharging operating area (2) and the third discharging operating area (3) corresponds to the higher-voltage discharge area.

Also, in the regenerative braking condition during the performance mode, the first high-voltage battery MB using the lower voltage is used in the first charging operating area (1)′ and the fourth charging operating area (4)′, and the second high-voltage battery SB using the higher voltage is used in the second charging operating area (2)′ and the third charging operating area (3)′. In other words, in performance mode, each of the first charging operating area ((1)′) and the fourth charging operating area ((4)′) corresponds to the low-voltage charging area, and each of the second charging operating area ((2)′) and the third charging operating area ((3)′) corresponds to the higher-voltage charging area.

Hereinafter, the learning data is described.

In step S100, the first controller Ctrl 1 learns a driver's driving habit data for each driving condition using a navigation device and stores the learned data in a memory.

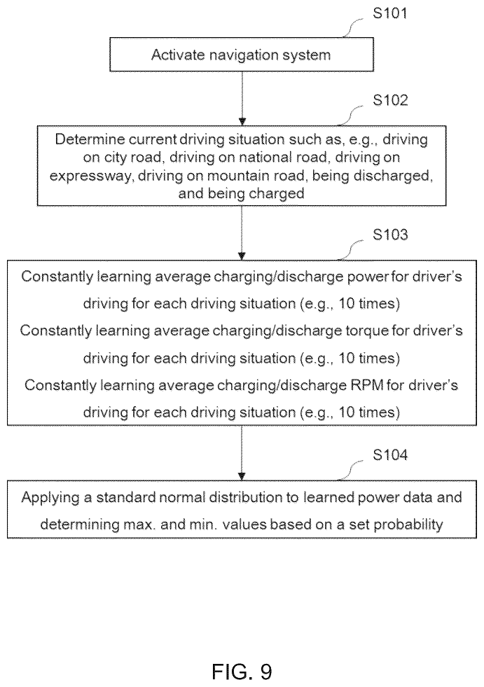

Hereinafter, this is described in detail with reference to FIG. 9.

The first controller Ctrl 1 activates the navigation device in step S101 to determine a driving condition based on map data in step S102.

Although the map data may be. e.g., map data for navigation of an audio video navigation (AVN), the embodiment of the present disclosure is not limited thereto.

The driving condition may be, e.g., based on a road type indicated by the map data.

For example, the driving condition may be distinguished, based on the map data, into a city road section, a mountainous up-hill section, a mountainous down-hill section, a highway section, and a national road section and may be distinguished into a discharge condition and a charge condition by regenerative braking.

In other words, the first controller Ctrl 1 may determine whether the driving condition corresponds to a city road, national road, highway, or mountainous road driving condition and whether it is a discharge condition or a charge condition caused by regenerative braking.

The city road section may include a road section defined as the city road in the map data. The mountainous section may include a road section defined as the mountainous road in the map data. Additionally, the highway section and the national road section may include a road section defined as a highway and a road section defined as a national road, respectively, in the map data.

Hereinafter, a process of acquiring a driver's driving habit data for each driving condition is described.

In step S103, the first controller Ctrl 1 may acquire real-time data on the power supplied to the driving motor M, i.e., discharge power data of the battery MB or SB, based on output requested by the driver while the host vehicle travels over a preset driving distance for each driving condition corresponding to each road type to determine average discharge power during the corresponding driving distance and repeat this process a preset number of times, thereby acquiring average discharge power data.

Similarly, the first controller Ctrl 1 may acquire (e.g., collect) real-time data on charge power data of the battery MB or SB by generation of the driving motor M caused by the regenerative braking. This data is gathered for each driving condition corresponding to each road type to determine average charge power during the corresponding driving distance and repeat this process a preset number of times, thereby acquiring average charge power data.

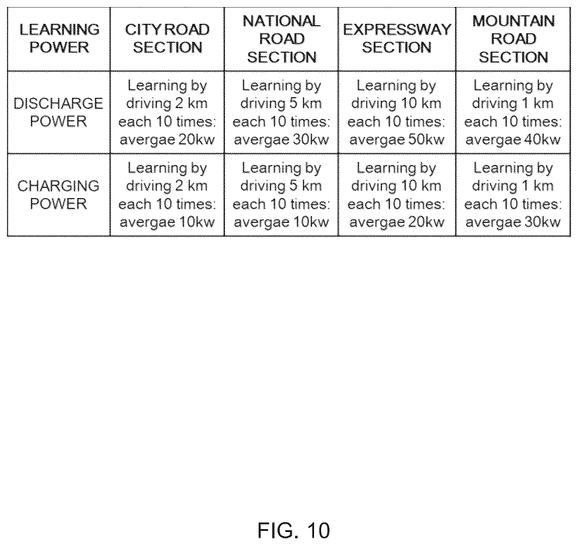

FIG. 10 shows an example of acquiring average power through learning for each driving condition, which is described below.

First, average discharge power for discharge power obtained while driving 2 km on the city road section for 10 repetitions is 20 kilowatt (kw).

Also, the average charge power for charge power obtained while driving 2 km on the city road section for 10 repetitions is 10 kw.

Average discharge power for discharge power obtained while driving 5 km on the national road section for 10 repetitions is 30 kw, and the average charge power for charge power obtained while driving 5 km on the national road section for 10 repetitions is 10 kw.

Average discharge power for discharge power obtained while driving 10 km on the highway section for 10 repetitions is 50 kw, and the average charge power for charge power obtained while driving 10 km on the highway section for 10 repetitions is 20 kw.

Also, average discharge power for discharge power obtained while driving 1 km on the mountainous road section for 10 repetitions is 40 kw, and the average charge power for charge power obtained while driving 1 km on the mountainous road section for 10 repetitions is 30 kw.

In step S103, the first controller Ctrl 1 may obtain average discharge torque data, average charge torque data, average discharge RPM data, and average charge RPM data for each driving condition using the same method.

Also, the data may be repeated for a preset number of repetition (e.g., 10 repetitions).

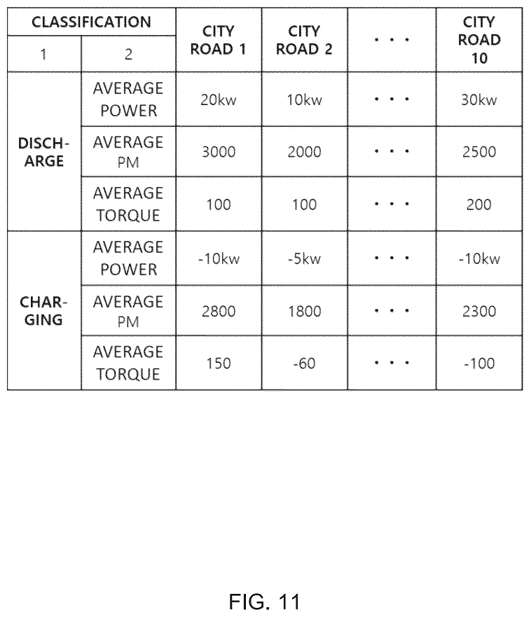

Through this, as shown as an example in FIG. 11, the average power data, average RPM data, and average torque data on the city road condition for 10 repetitions may be obtained for the discharge and charge conditions

In FIG. 11, the average discharge power data for “City 1” represents the average discharge power obtained while driving 2 km for 10 repetitions on the city road section, and the average discharge power data for “City 2” represents the average discharge power obtained while driving 2 km for 10 repetitions on a city road section different from that of “City 1” or during a driving condition at a different time.

Thereafter, in step S104, the first controller Ctrl 1 standardizes a normal distribution of the data obtained as described above and obtains learning data that is used as reference data based on a preset probability.

In other words, the first controller Ctrl 1 determines first discharge power and second discharge power, first charge power and second charge power, first discharge torque and second discharge torque, first charge torque and second charge torque, first discharge RPM and second discharge RPM, and first charge RPM and second charge RPM based on a probability that is set through a standard normal distribution.

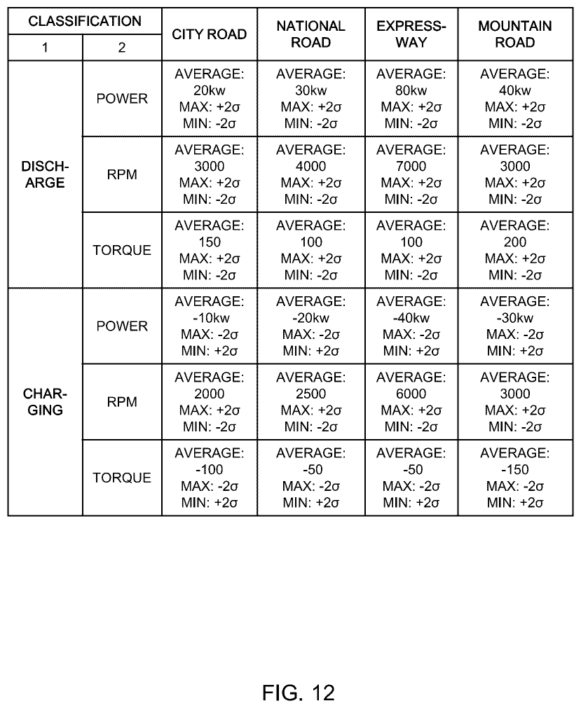

FIG. 12 shows an example of average data obtained by normalizing average data for each driving condition and maximum and minimum values determined based on a 98% probability from a standard normal distribution.

For example, in FIG. 12, the discharge learning data for “City” has an average of 20 kW, a maximum value is obtained by adding two times of a standard deviation σ to the average, and a minimum value is obtained by subtracting two times of the standard deviation σ from the average. The first discharge power may be derived from the maximum value, and the second discharge power may be derived from the minimum value.

Also, when based on a 99% probability, one times of the standard deviation σ may be applied instead of two times of the standard deviation σ.

The learning data for each driving condition in FIG. 12 may be used as reference data, which is described below. For reference, although the standard deviation for each driving condition is expressed by the same σ in FIG. 12; each standard deviation may be different.

First, when the learning data for the “City” driving condition in FIG. 12 is described as a representative example, the first discharge power is ‘20 kW+2σ’, the second discharge power is ‘20 kW−2σ’, the first discharge RPM is ‘3000+2σ’, the second discharge RPM is ‘3000-2σ’, the first discharge torque is ‘150+2σ’, the second discharge torque is ‘150−2σ’, the first charge power is ‘−10 kW−2σ’, the second charge power is ‘−10 kW+2σ’, the first charge RPM is ‘2000+2σ’, the second charge RPM is ‘2000−2σ’, the first charge torque is ‘−100−2σ’, and the second charge torque is ‘−100+2σ’.

The average values of FIG. 12 may be used as reference data to distinguish the plurality of operating areas. For example, respective reference lines of FIG. 7 may be determined by using the average values of FIG. 12.

When the “City” driving condition of FIG. 12 is described as an example, in FIG. 7, 20 kW may correspond to discharge power A, 3000 may correspond to K, and 150 may corresponds to Tdc in the discharge condition, and −10 kW may correspond to charge power B, 2000 may correspond to K, and −100 may correspond to Tc in the charge condition.

In other words, the operating areas in the discharge and charge conditions may be distinguished based on the learning data.

When the data of FIG. 12 is applied to the torque-RPM map, the operating areas may be distinguished for each driving condition.

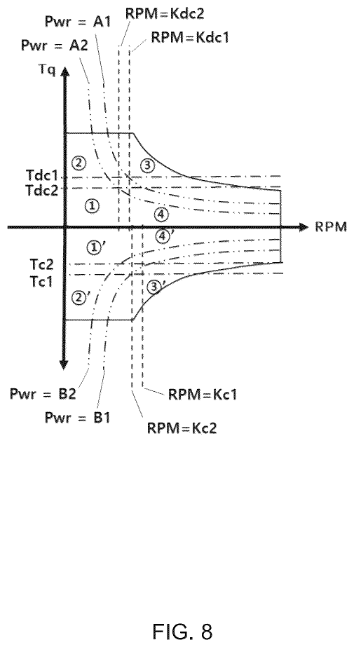

FIG. 8 shows an example in which the operating areas are distinguished based on the above-described learning data.

FIG. 8 shows that hysteresis sections of a set range (e.g., ±2σ) are defined by respective reference lines (derived from the average values of FIG. 12).

In other words, by using the data of FIG. 12, the hysteresis sections are defined by the first discharge power A1 line ‘Pwr=A1’ and the second discharge power A2 line ‘Pwr=A2’ of FIG. 8, the hysteresis sections are defined by ‘Tq=Tdc1’ and ‘Tq=Tdc2’, and hysteresis sections are defined by ‘RPM=Kdc1’ and ‘RPM=Kdc2’. Also, for the charge condition, hysteresis sections are defined by the first charge power B1 line ‘Pwr=B1’ and the second charge power B2 line ‘Pwr=B2’, hysteresis sections are defined by ‘Tq=Tc1’ and ‘Tq=Tc2’, and hysteresis sections are defined by ‘RPM=Kc1’ and ‘RPM=Kc2’.

Referring to FIG. 3 again, the first controller Ctrl 1 performs a control processes of step S25, S30, or S40 depending on whether the driving mode is a normal mode or a performance mode, which is described below.

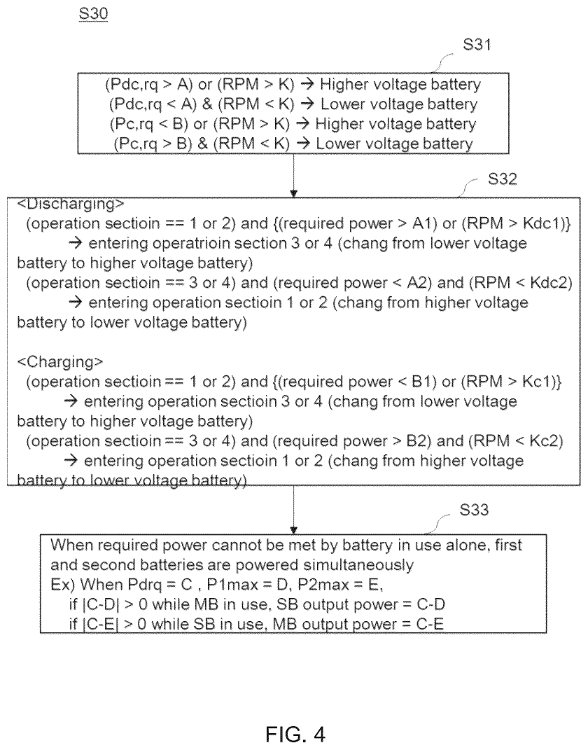

First, battery operating control in the normal mode in step S30 is shown in FIG. 4.

In step S31, the first controller Ctrl 1 determines a battery to be used among the first high-voltage battery MB and the second high-voltage battery SB based on an operating characteristic of the driving motor M, i.e., RPM and power.

As described above, the discharge power A, the charge power B, and the reference RPM K in step S31 may be determined from learning data as in FIG. 12. Thus, the battery to be used is determined as follows.

In step S31, the first controller Ctrl 1 determines to use the second high-voltage battery SB as the battery to be used when the requested power Pdc,rp is greater than the discharge power A.

Also, the first controller Ctrl 1 determines the second high-voltage battery SB as the battery to be used when the RPM is greater than the reference RPM K.

Also, the first controller Ctrl 1 determines to use the first high-voltage battery MB using the lower voltage as the battery to be used when the requested power Pdc,rq is less than the discharge power and the RPM is less than the reference RPM K.

Also, the first controller Ctrl 1 determines to use the second high-voltage battery SB using the higher voltage as the battery to be used when the requested regenerative braking power Pc,rq is less than the charge power B.

Also, the first controller Ctrl 1 determines to use the second high-voltage battery SB using the higher voltage as the battery to be used when the RPM is greater than the reference RPM K in the regenerative braking condition.

Also, the first controller Ctrl 1 determines to use the first high-voltage battery MB using the lower voltage as the battery to be used when the requested regenerative braking power Pc,rq is greater than the charge power B and the RPM is less than the reference RPM K.

Also, the first controller Ctrl 1 uses the above-described hysteresis section when determining transition of the operating areas and determines the battery to be used based on the transition in step S32.

In other words, in step S32, when the driving mode is the normal mode, the current operating characteristic (e.g., operating point) is disposed in the first discharging operating area or the second discharging operating area, and the required power is greater than the first discharge power A1 or the RPM is greater than the first discharge RPM Kdc1, the battery using the higher voltage among the first battery and the second battery is determined to be used.

In this case, when the current operating characteristic is disposed in the third discharging operating area or the fourth discharging operating area, and the required power is less than the second discharge power A2 and the RPM is less than the second discharge RPM Kdc2, the battery using the lower voltage among the first battery and the second battery is determined to be used.

In this case, when the current operating characteristic is disposed in the first charging operating area or the second charging operating area, and the required power is less than the first charge power B1 or the RPM is greater than the first charge RPM Kc1, the battery using the higher voltage is determined as the battery to be used.

Also, in this case, when the current operating characteristic is disposed in the third charging operating area or the fourth charging operating area, and the required power is greater than the second charge power B2 and the RPM is less than the second charge RPM Kc2, the battery using the lower voltage is determined as the battery to be used.

Also, when the determined battery alone may not satisfy the required power after the higher-voltage battery or lower-voltage battery is determined, the other battery may be determined to be used together in step S33.

For example, when it is assumed that the driver's required power Pdrq is C, the maximum output power P1max of the first high-voltage battery MB is D, and the maximum output power P1max of the second high-voltage battery MB is E, and when it is determined that the maximum output power P1max is less than C that is the driver's required power Pdrq after the first high-voltage battery MB is determined to be used, the second high-voltage battery SB is used to compensate for the shortage C-D. In this case, when it is determined that the maximum output power P2max of the second high-voltage battery SB is less than C that is the driver's required power Pdrq after the second high-voltage battery SB is determined to be used, the first high-voltage battery MB is used to compensate for the shortage C-E.

Hereinafter, battery operating control in the performance mode in step S40 is described with reference to FIG. 5.

In step S41, when the RPM is equal to or less than the reference RPM K (YES in step S41), the torque control mode in step S42 is performed. When the RPM is greater than the reference RPM K (NO in step S41), the power control mode in step S43 is performed.

In step S42, the first controller Ctrl 1 determines to use the second high-voltage battery SB using the higher voltage when the required torque is greater than the discharge torque Tdc and determines to use the first high-voltage battery MB using the lower voltage when the required torque is less than the discharge torque Tdc.

Also, the first controller Ctrl 1 determines to use the second high-voltage battery SB when the regenerative braking required torque is less than the charge torque Tc and determines to use the first high-voltage battery MB using the lower voltage when the regenerative braking required torque is greater than the charge torque Tc.

On the other hand, in step S43, the first controller Ctrl 1 determines to use the second high-voltage battery SB using the higher voltage when the required power Pdc,rq is greater than the discharge power A and determines to use the first high-voltage battery MB using the lower voltage when the required power Pdc,rq is less than the discharge power A.

Also, the first controller Ctrl 1 determines to use the second high-voltage battery SB using the higher voltage when the regenerative braking required power Pc,rq is less than the charge power B and determines to use the first high-voltage battery MB using the lower voltage when the regenerative braking required power Pc,rq is greater than the charge power B.

Also, even in the performance mode, the first controller Ctrl 1 uses the above-described hysteresis section when determining the transition of the operating areas and determines the battery to be used based on the transition in step S44.

In other words, in step S44, when the current operating characteristic is disposed in the first discharging operating area or the fourth discharging operating area and the required power of the operating characteristic is greater than the first discharge power A1 or the required torque is greater than the first discharge torque Tdc1, the battery using the higher voltage is determined as the battery to be used.

In this case, when the current operating characteristic is disposed in the second discharging operating area or the third discharging operating area and the required power is less than the second discharge power B2 and the required torque is less than the second discharge RPM Kdc2, the battery using the lower voltage is determined as the battery to be used.

Also, in this case, when the current operating characteristic is disposed in the first charging operating area or the fourth charging operating area, and the required power is less than the first charge power B1 or the required torque is less than the first charge torque Tc1, the battery using the higher voltage is determined as the battery to be used.

In this case, when the current operating characteristic is disposed in the second charging operating area or the third charging operating area, and the required power is greater than the second charge power B2 and the required torque is greater than the second charge torque Tc2, the battery using the lower voltage is determined as the battery to be used.

Even in the performance mode, when the determined battery alone may not satisfy the required power after the higher-voltage battery or lower-voltage battery is determined, the other battery may be determined to be used together in step S45. In this embodiment, since step S45 is the same as the above-described step S33, a detailed description thereof has been omitted.

On the other hand, in this embodiment, the general mode that is a low-power mode may include at least one of a normal mode, a comfort mode, an eco-mode, and a smart mode, and the performance mode that is a high-torque mode may include at least one of a sports mode and a track mode.

For example, the normal mode that is a general driving mode may maintain a balance between a performance and a fuel efficiency of the vehicle.

For example, the comfort mode may be set to allow a driver to feel comfort in acceleration, braking, and riding.

For example, the eco mode may optimize the fuel efficiency of the vehicle. In the eco mode, since the acceleration decreases and the transmission gear ratio increases, energy consumption may be relatively reduced. The eco mode may also include control that automatically turns off an air-conditioner to reduce electricity usage.

For example, the sports mode may maximize the performance of the vehicle. In the sports mode, as an output of the first drive motor M increases, and the transmission gear ratio decreases, the vehicle may be rapidly accelerated. Also, the sports mode may include control that enhances steering assistant force and strengthen a suspension system, and through this, speedier driving may be achieved.

The track mode may be configured for driving on a dedicated race track, e.g., a track mode supported in Tesla vehicles. In the track mode, settings for stability control, traction control, regenerative braking, and a cooling system may be changed to improve a performance and handling.

The driving mode may be selected by the driver.

In other words, the first controller Ctrl 1 may verify whether one of a plurality of driving modes is selected by the driver.

For example, the selection of the driving mode by the driver may be achieved by an input of the driver through an AVN screen or an input through an input unit such as a button, a joystick, or a dial disposed in the first mobility MLT1.

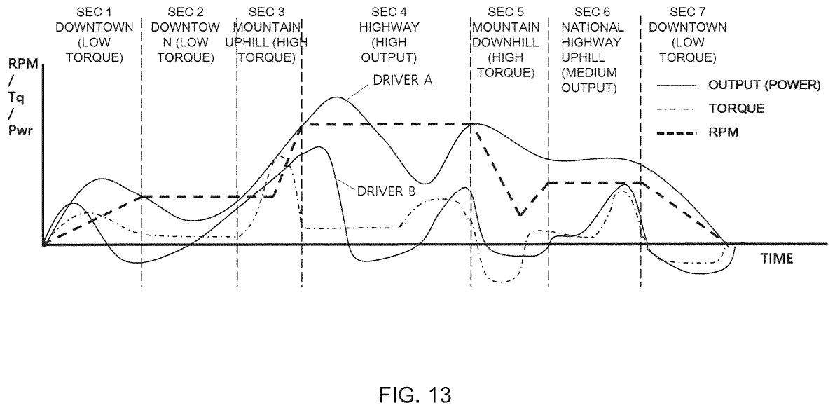

FIG. 13 shows a hypothetical example of a driving simulation according to an embodiment of the present disclosure, which is described below.

First, FIG. 13 shows RPM, torque, and power of the first driving motor M based on driving time.

Referring to FIG. 13, the first mobility MLT1 drives from a first driving section SEC1 to a seventh driving section SEC7. The first driving section SEC1 represents a low-torque driving condition on a city road, and a second driving section SEC2 represents a low-power driving condition on the city road.

In FIG. 13, a third driving section SEC3 represents a high-torque driving condition as an up-hill driving on a mountainous road, and a fourth driving section SEC4 represents a high-power driving condition as a highway driving.

Also, the fourth driving section SEC4 represents a high-torque regenerative braking condition on the mountain road, and a sixth driving section SEC6 represents a medium-power driving condition during up-hill driving on a national highway.

Lastly, the seventh driving section SEC7 represents a low-torque driving condition on the city road.

Since the battery is determined based on learning data of each of drivers A and B for the above-described driving conditions, driving results may be different from each other.

In other words, as shown in FIG. 13, even for the same driving course, output power profiles of the driver A and the driver B during driving may be different because battery operating strategies are determined based on different learning data.

In the embodiments of the present disclosure, the reference data that distinguishes the operating areas is determined based on learning or settings of a system that is a non-learning method.

Hereinafter, adjustment of the reference data is described.

In this embodiment, the adjustment of the reference data may be performed in step S20 of FIG. 3.

To this end, the first controller Ctrl 1 may determine adjustment parameters.

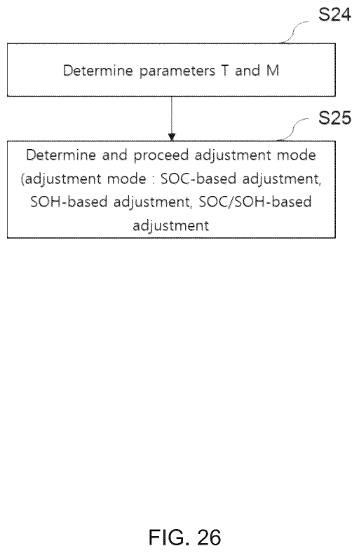

In step S24 of FIG. 26, T and M may be determined by using mathematical equations 3 and 9 that are described below.

Thereafter, in step S25, the adjustment mode may be determined based on the SOCs and/or SOHs of the first battery MB and the second battery SB.

In this embodiment, the adjustment mode include a SOC-based adjustment, a SOH-based adjustment, and an adjustment that performs both the SOC-based adjustment and the SOH-based adjustment (hereinafter, referred to as a SOC/SOH-based adjustment).

The first controller Ctrl 1 may determine whether a first condition, a second condition, and a third condition, which are set based on states of the SOC (hereinafter, referred to as “first SOC”) and SOH (hereinafter, referred to as “first SOH”) of the lower-voltage battery and the SOC (hereinafter referred to as “second SOC”) and SOH (hereinafter referred to as “second SOH”) of the higher-voltage battery among the first battery MB and the second battery SB, are satisfied, and then, based on results, determine the adjustment mode.

In this embodiment, the first condition is as follows:

$$! ( SOCth 1 < first SOC < SOCth 2 ) or ! ( SOCth 1 < second SOC < SOCth 2 )$$

The second condition is as follows:

$$( SOCth 1 < first SOC < SOCth 2 ) and ( SOCth 1 < second SOC < SOCth 2 )$$

Also, the third condition is as follows:

$$\begin{matrix}( SOCth 1 < first SOC < SOCth 2 ) and ( SOCth 1 < second SOC < SOCth 2 ) and ( Δ SOC < \\ Δ SOCth ) and ! ( SOHth 1 < Δ SOH < SOHth 2 )\end{matrix}$$

SOCth1 may represent a first set SOC that is 20% for example. SOCth2 may represent a second reference SOC that is 80% for example. Also, SOHth1 may represent the first reference SOH that is 1% for example. SOHth2 may represent the second reference SOH that is 5% for example.

Also, ΔSOC represents a difference between the first SOC and the second SOC. ΔSOCth represents a set SOC difference. ΔSOH represents a difference between the first SOH and the second SOH.

In step S25, the first controller Ctrl 1 determines the SOC-based adjustment as the adjustment mode when the first condition is satisfied, the SOH-based adjustment as the adjustment mode when the second condition is satisfied, and the SOC/SOH-based adjustment as the adjustment mode when the third condition is satisfied.

According to the third condition, the SOC-based adjustment is not performed when a difference between SOHs of the two batteries is less than 1%, and the SOH-based adjustment is performed when a difference between SOHs of the two batteries is greater than 5%.

Hereinafter, each adjustment mode is described in detail.

### SOC-Based Adjustment

The SOC-based adjustment includes a first SOC-based adjustment of adjusting the reference data based on a first mode oriented towards charging a lower-voltage battery and/or discharging a higher-voltage battery and/or a second SOC-based adjustment of adjusting the reference data based on a second mode oriented towards discharging the lower-voltage battery and/or charging the higher-voltage battery.

Also, the first SOC-based adjustment may be performed when the first SOC is less than the second SOC.

Also, the second adjustment may be performed when the first SOC is greater than the second SOC.

On the other hand, the reference data may be maintained without any adjustment when the first SOC is the same as the second SOC.

The first SOC-based adjustment may include adjusting the reference data to expand the higher-voltage discharging area and/or lower-voltage charging area, and the second SOC-based adjustment may include adjusting the reference data to expand the lower-voltage discharging area and/or higher-voltage charging area in the plurality of operating areas.

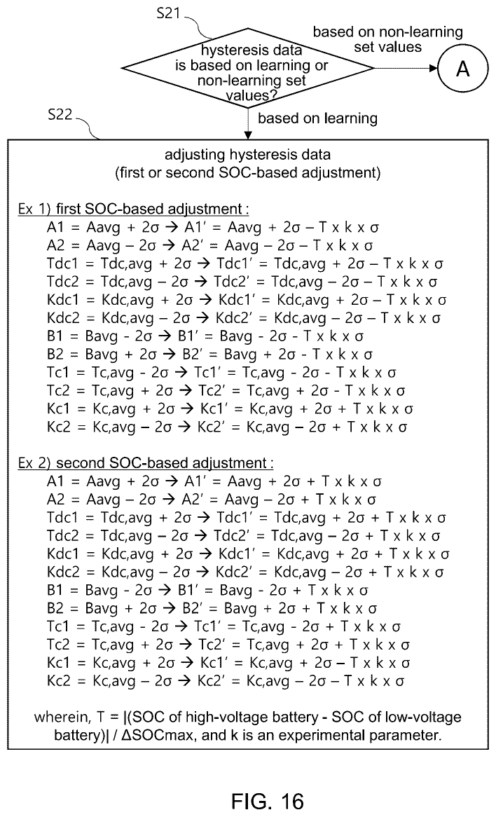

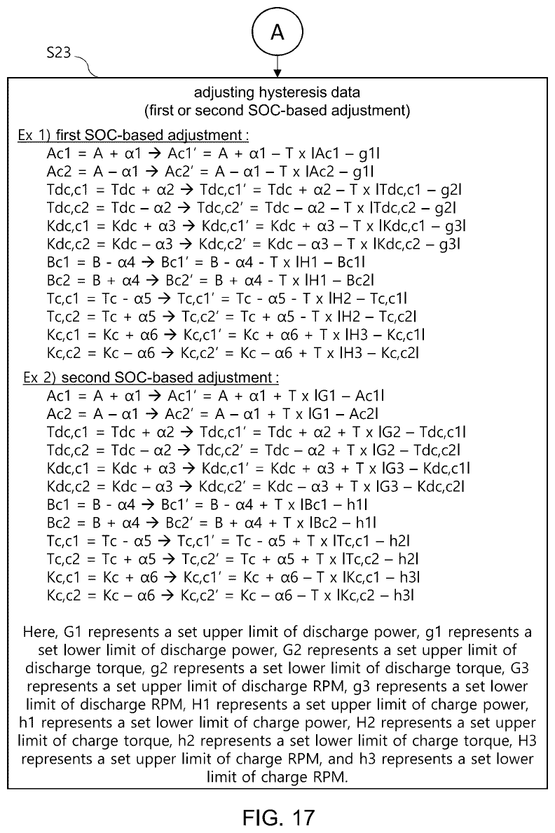

As shown in FIGS. 16 and 17, in this embodiment, the SOC-based adjustment may be performed differently depending on the determination result in step S21 of whether the hysteresis data is based on learning or non-learning set values.

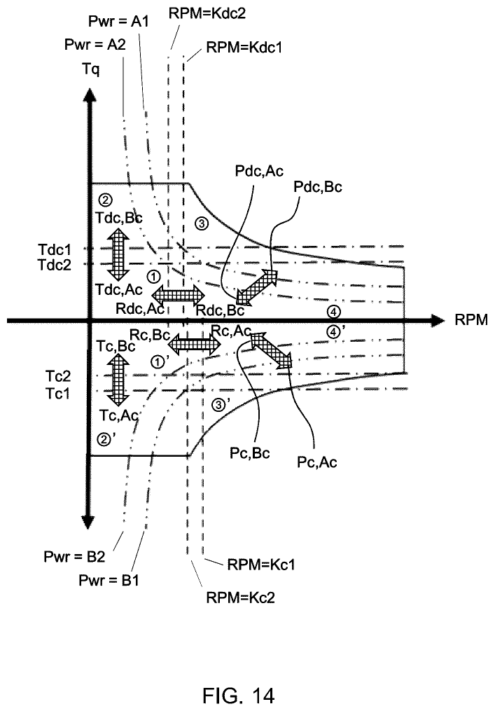

First, step S22 of FIG. 16 shows an example of a case based on learning, which is described with reference to FIG. 14.

FIG. 14 shows a concept of the adjustment of the reference data in FIG. 8.

Referring to FIG. 14, as described above, the discharging power reference hysteresis is determined by the first discharging power A1 line “Pwr=A1” and the second discharge power A2 line “Pwr=A2”. The discharge torque reference hysteresis is defined by the equivalent torque lines “Tq=Tdc1” and “Tq=Tdc2,” and the discharge RPM reference hysteresis is defined by the equivalent RPM lines “RPM=Kdc1” and “RPM=Kdc2”. The charge power reference hysteresis is determined by the first charge power B1 line “Pwr=B1,” and the second charge power B2 line “Pwr=B2”. The charge torque reference hysteresis is defined by the equivalent torque lines “Tq=Tc1” and “Tq=Tc2”, and the charge RPM reference hysteresis is defined by the equivalent RPM lines “RPM=Kc1” and “RPM=Kc2.”

Also, the first SOC-based adjustment includes the first SOC-based discharging power adjustment Pdc,Ac, the first SOC-based discharging torque adjustment Tdc,Ac, the first SOC-based discharging RPM adjustment Rdc,Ac, the first SOC-based charging power adjustment Pc,Ac, the first SOC-based charging torque adjustment Tc,Ac, and the first SOC-based charge RPM adjustment Rc,Ac. The second SOC-based adjustment includes the second SOC-based discharging power adjustment Pdc,Bc, the second SOC-based discharging torque adjustment Tdc,Bc, the second SOC-based discharging RPM adjustment Rdc,Bc, the second SOC-based charging power adjustment Pc,Bc, the second SOC-based charging torque adjustment Tc,Bc, and the second SOC-based charging RPM adjustment Rc,Bc.

In this embodiment, the first SOC-based adjustment may be determined by Equation 2 below, and the second SOC-based adjustment may be determined by Equation 3 below.

$$[ Mathematical equation 2 ]$$

$$\begin{matrix}A 1 = Aavg + 2 σ \to A 1 ’ = Aavg + 2 σ - T x k 1 x σ \\ A 2 = Aavg - 2 σ \to A 2 ’ = Aavg - 2 σ - T x k x σ \\ Tdc 1 = Tdc , avg + 2 σ \to Tdc 1 ’ = Tdc , avg + 2 σ - T x k x σ \\ Tdc 2 = Tdc , avg - 2 σ \to Tdc 2 ’ = Tdc , avg - 2 σ - T x k x σ \\ Kdc 1 = Kdc , avg + 2 σ \to Kdc 1 ’ = Kdc , avg + 2 σ - T x k x σ \\ Kdc 2 = Kdc , avg - 2 σ \to Kdc 2 ’ = Kdc , avg - 2 σ - T x k x σ \\ B 1 = Bavg - 2 σ \to B 1 ’ = Bavg - 2 σ - T x k x σ \\ B 2 = Bavg + 2 σ \to B 2 ’ = Bavg + 2 σ - T x k x σ \\ Tc 1 = Tc , avg - 2 σ \to Tc 1 ’ = Tc , avg - 2 σ - T x k x σ \\ Tc 2 = Tc , avg + 2 σ \to Tc 2 ’ = Tc , avg + 2 σ - T x k x σ \\ Kc 1 = Kc , avg + 2 σ \to Kc 1 ’ = Kc , avg + 2 σ + T x k x σ \\ Kc 2 = Kc , avg - 2 σ \to Kc 2 ’ = Kc , avg - 2 σ + T x k x σ\end{matrix}$$

$$[ Mathematical equation 3 ]$$

$$\begin{matrix}A 1 = Aavg + 2 σ \to A 1 ’ = Aavg + 2 σ + T x k x σ \\ A 2 = Aavg - 2 σ \to A 2 ’ = Aavg - 2 σ + T x k x σ \\ Tdc 1 = Tdc , avg + 2 σ \to Tdc 1 ’ = Tdc , avg + 2 σ + T x k x σ \\ Tdc 2 = Tdc , avg - 2 σ \to Tdc 2 ’ = Tdc , avg - 2 σ + T x k x σ \\ Kdc 1 = Kdc , avg + 2 σ \to Kdc 1 ’ = Kdc , avg + 2 σ - T x k x σ \\ Kdc 2 = Kdc , avg - 2 σ \to Kdc 2 ’ = Kdc , avg - 2 σ - T x k x σ \\ B 1 = Bavg - 2 σ \to B 1 ’ = Bavg - 2 σ + T x k x σ \\ B 2 = Bavg + 2 σ \to B 2 ’ = Bavg + 2 σ + T x k x σ \\ Tc 1 = Tc , avg - 2 σ \to Tc 1 ’ = Tc , avg - 2 σ + T x k x σ \\ Tc 2 = Tc , avg + 2 σ \to Tc 2 ’ = Tc , avg + 2 σ + T x k x σ \\ Kc 1 = Kc , avg + 2 σ \to Kc 1 ’ = Kc , avg + 2 σ - T x k x σ \\ Kc 2 = Kc , avg - 2 σ \to Kc 2 ’ = Kc , avg - 2 σ - T x k x σ\end{matrix}$$

T is determined by Equation 4 below: in which k is a test parameter.

$$[ Mathematical equation 4 ]$$

$$T = \vert ( SOC of high - voltage battery - SOC of low - voltage battery ) \vert / Δ SOC max$$

In other words, T is determined based on a difference between the current SOC of the battery using the higher voltage and the current SOC of the battery using the lower voltage among the first battery MB and the second battery SB.

ΔSOC max represents a possible difference between the first battery MB and the second battery SB, and this may be determined in advance as a set value. For example, since a theoretically possible difference between the two SOCs is 100%, the difference may be set to 100. However, the difference may be set to a value less than 100 in consideration of a substantial condition.

T is a parameter representing the SOC state of the higher-voltage battery and the lower-voltage battery. As shown in Equations 2 and 3, in this embodiment, the adjustment amount for hysteresis adjustment is determined using the standard deviation σ along with the T parameter and the k parameter.

In the first SOC-based adjustment, the discharging reference hysteresis is adjusted to be shifted in a direction that reduces the first discharging operating area (1) by ‘T×k×σ’, and the charging reference hysteresis is also adjusted to be shifted in a direction that expands the first charging operating area (1) by an absolute value of ‘T×k×σ’.

Also, in the second SOC-based adjustment, the discharge reference hysteresis is adjusted to be shifted in a direction that expands the first discharging operating area (1) by ‘T×k×σ’, and the charging reference hysteresis is also adjusted to be shifted in a direction that reduces the first charging operating area (1)′ by an absolute value of ‘T×k×σ’.

On the other hand, the test parameter k may be determined by performing a test driving based on the above-described adjustment and then verifying whether the difference between SOCs of the first battery MB and the second battery SB substantially decreases. In other words, the k may be determined by performing a plurality of test drives while varying k and then selecting a smallest difference between the SOHs of two batteries among the test drives.

When the hysteresis is not based on learning in step S21 of FIG. 16, step S23 of FIG. 17 is performed, which is described below.

In this case, the hysteresis that is the reference data is determined by the system as a default instead of learning.

For example, the hysteresis may be determined by applying ±α to each of reference discharging power A, reference discharge torque Tdc, reference discharge RPM Kdc (the reference RPMs may be different for a discharging condition and a charging condition although the reference RPMs for the discharging condition and the charging condition are expressed as the same K in FIG. 7), reference charging power B, reference charging torque Tc. and reference charging RPM Kc.

For example, equivalent-power lines ‘Pwr=Ac1’ and ‘Pwr=Ac2’ may be determined by applying a first set value al to the power A. Equivalent-torque lines ‘Tq=Tdc,c1’ and ‘Tq=Tdc,c2’ may be determined by applying a second set value α2 to torque Tdc. Equivalent-RPM lines ‘RPM=Kdc,c1’ and ‘RPM=Kdc,c2’ may be determined by applying a third set value α3 to RPM Kdc. Equivalent-power lines ‘PWr=Bc1’ and ‘Pwr=Bc2’ may be determined by applying a fourth set value α4 to power B. Equivalent-torque lines ‘Tq=Tc,c1’ and ‘Tq=Tc,c2’ may be determined by applying a fifth set value α5 to torque Tc. Equivalent-RPM lines ‘RPM=Kc,c1’ and ‘RPM=Kc,c2’ may be determined by applying a sixth set value α6 to RPM Kc.

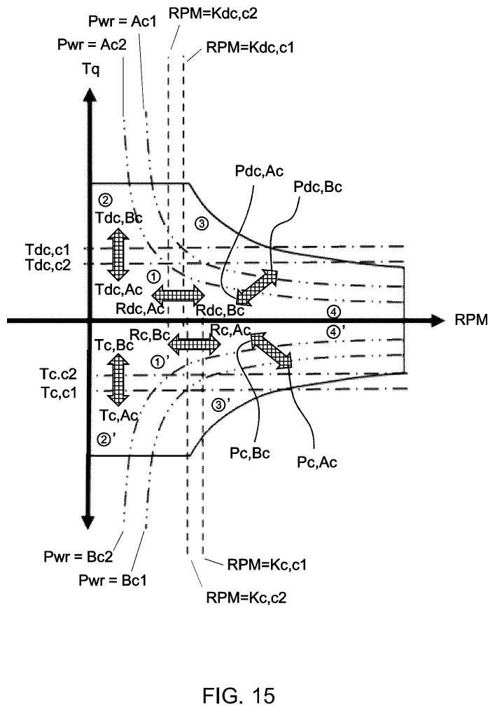

In FIG. 15, the discharging power reference hysteresis is determined by the first discharging power Ac1 line ‘Pwr=Ac1’ and the second discharging power Ac2 line ‘Pwr=Ac2’. The discharge torque reference hysteresis is determined by the equivalent torque lines ‘Tq=Tdc,c1’ and ‘Tq=Tdc,c2’. The discharge RPM reference hysteresis is determined by the equivalent RPM lines ‘RPM=Kdc,c1’ and ‘RPM=Kdc,c2’. The charging power reference hysteresis is determined by the first charging power Bc1 line ‘Pwr=Bc1’ and the second charging power Bc2 line ‘Pwr=Bc2’. The charging torque reference hysteresis is determined by the equivalent torque lines ‘Tq=Tc,c1’ and ‘Tq=Tc,c2’, and the charging RPM reference hysteresis is determined by the equivalent RPM lines ‘RPM=Kc,c1’ and ‘RPM=Kc,c2’.

In the adjustment of step S23 in FIG. 17, first SOC-based discharging power adjustment Pdc,A, first SOC-based discharging torque adjustment Tdc,A, first SOC-based discharging RPM adjustment Rdc,A, first SOC-based charging power adjustment Rc,A, first SOC-based charging torque adjustment Tc,A, and first SOC-based charging RPM adjustment Rc,A may be determined by Equation 5 below.

$$\begin{matrix}[ Mathematical equation 5 ] & \end{matrix}$$

$$\begin{matrix}Ac 1 = A + α 1 \to Ac 1 ’ = A + α 1 - T x 1 Ac 1 - g 11 \\ Ac 2 = A - α 1 \to Ac 2 ’ = A - α 1 - T x 1 Ac 2 - g 11 \\ Tdc , c 1 = Tdc + α 2 \to Tdc , c 1 ’ = Tdc + α 2 - T x lTdc , c 1 - g 21 \\ Tdc , c 2 = Tdc - α 2 \to Tdc , c 2 ’ = Tdc - α 2 - T x lTdc , c 2 - g 21 \\ Kdc , c 1 = Kdc + α 3 \to Kdc , c 1 ’ = Kdc + α 3 - T x lKdc , c 1 - g 31 \\ Kdc , c 2 = Kdc + α 3 \to Kdc , c 2 ’ = Kdc + α 3 - T x lKdc , c 2 - g 31 \\ Bc 1 = B - α 4 \to Bc 1 ’ = B - α 4 - T x lH 1 - Bc 11 \\ Bc 2 = B + α 4 \to B 2 ’ = B + α 4 - T x lH 1 - Bc 21 \\ Tc , c 1 = Tc - α 5 \to Tc , c 1 ’ = Tc - α 5 - T x lH 2 - Tc , c 11 \\ Tc , c 2 = Tc + α 5 \to Tc , c 2 ’ = Tc + α 5 + T x lH 2 - Tc , c 21 \\ Kc , c 1 = Kc + α 6 \to Kc , c 1 ’ = Kc + α 6 + T x lH 3 - Kc , c 11 \\ Kc , c 2 = Kc - α 6 \to Kc , c 2 ’ = Kc - α 6 + T x lH 3 - Kc , c 21\end{matrix}$$

Also, in the adjustment of step S23 in FIG. 17, second SOC-based discharging power adjustment Pdc,B, second SOC-based discharging torque adjustment Tdc,B, second SOC-based discharging RPM adjustment Rdc,B, second SOC-based charging power adjustment Pc,B, second SOC-based charging torque adjustment Tc,B, and second SOC-based charging RPM adjustment Rc,B may be determined through Equation 6 below.

$$\begin{matrix}[ Mathematical equation 6 ] & \end{matrix}$$

$$\begin{matrix}Ac 1 = A + α 1 \to Ac 1 ’ = A + α 1 - T x 1 G 1 - Ac 11 \\ Ac 2 = A - α 1 \to Ac 2 ’ = A - α 1 - T x 1 G 1 - Ac 21 \\ Tdc , c 1 = Tdc + α 2 \to Tdc , c 1 ’ = Tdc + α 2 + T x lG 2 - Tdc , c 11 \\ Tdc , c 2 = Tdc - α 2 \to Tdc , c 2 ’ = Tdc - α 2 + T x lG 2 - Tdc , c 21 \\ Kdc , c 1 = Kdc + α 3 \to Kdc , c 1 ’ = Kdc + α 3 + T x lG 3 - Kdc , c 11 \\ Kdc , c 2 = Kdc - α 3 \to Kdc , c 2 ’ = Kdc - α 3 + T x lG 3 - Kdc , c 21 \\ Bc 1 = B - α 4 \to Bc 1 ’ = B - α 4 - T x lBc 1 - h 11 \\ Bc 2 = B + α 4 \to Bc 2 ’ = B + α 4 - T x lBc 2 - h 11 \\ Tc , c 1 = Tc - α 5 \to Tc , c 1 ’ = Tc - α 5 - T x lT , c 2 - h 21 \\ Tc , c 2 = Tc + α 5 \to Tc , c 2 ’ = Tc + α 5 + T x lTc , c 2 - h 21 \\ Kc , c 1 = Kc + α 6 \to Kc , c 1 ’ = Kc + α 6 - T x lKc , c 1 - h 31 \\ Kc , c 2 = Kc - α 6 \to Kc , c 2 ’ = Kc - α 6 - T x lKc , c 2 - h 31\end{matrix}$$

G1 represents a set upper limit for discharging power, g1 represents a set lower limit for discharging power, G2 represents a set upper limit for discharging torque, g2 represents a set lower limit for discharging torque, G3 represents a set upper limit for discharging RPM, g3 represents a set lower limit for discharging RPM, H1 represents a set upper limit for charging power, h1 represents a set lower limit for charging power, H2 represents a set upper limit for charging torque, h2 represents a set lower limit for charging torque, H3 represents a set upper limit for charging RPM, and h3 represents a set lower limit for charging RPM, which may be determined as set values.

For example, G1 and g1 may be a maximum power and a minimum power of the driving motor M, respectively.

Similarly, when the hysteresis is adjusted to be shifted, this shifting does not exceed the upper or lower limits in consideration of absolute values of differences between the above-described upper or lower limits and the reference before being adjusted.

For example, when adjusting the equivalent power line ‘Pwr=Ac1,’ a adjustment amount of the shifting is determined by multiplying T that is the SOC parameter to an absolute value of the difference between power Ac1 and g1, so that the adjustment does not exceed the set lower limit of the discharging power even when T has a maximum value of 1.

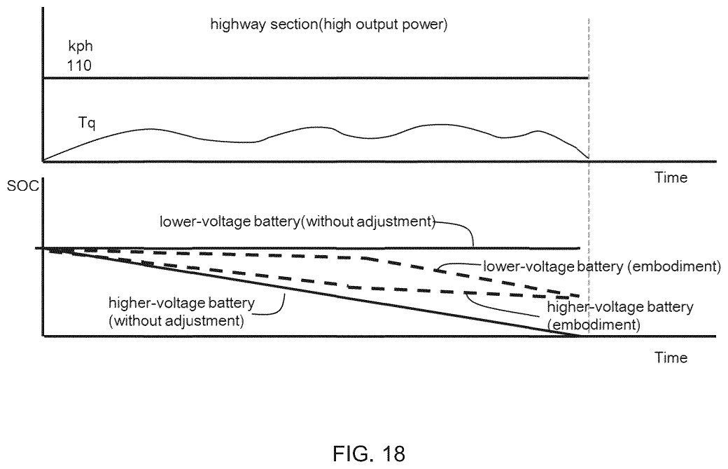

FIG. 18 conceptually shows SOCs of the higher-voltage battery and the lower-voltage battery in a case when the adjustment of the above-described reference data is performed and a case when the adjustment is not performed for an assumed condition of driving at a speed of 110 kph on a highway section.

As shown in FIG. 18, when the adjustment of the reference data is not performed, only a higher-voltage battery is used because it is a high-output condition. Accordingly, although the SOC of the higher-voltage battery is significantly reduced after the driving is completed, the lower-voltage battery is not used to maintain the SOC thereof.

On the other hand, when the adjustment of the reference data is performed, the lower-voltage discharging area is adjusted to be expanded, and the lower-voltage battery is used. Accordingly, after the driving is completed, the SOCs of both batteries become relatively similar.

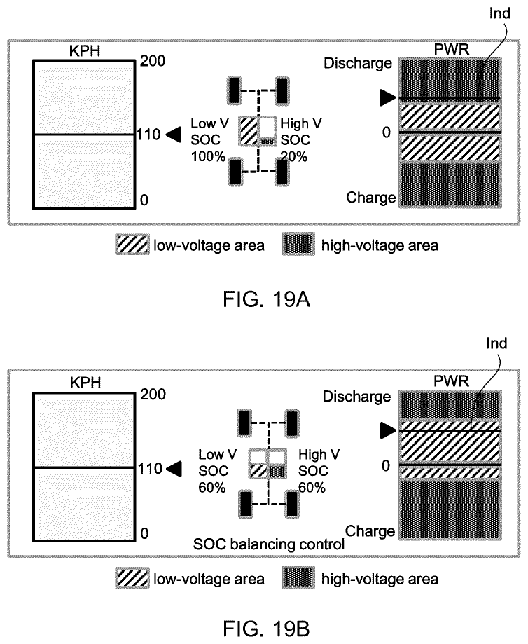

This adjustment of the reference data may be displayed on an instrument cluster in the vehicle, which is illustrated in FIGS. 19A and 19B.

FIG. 19A shows that, when the adjustment is not performed in a condition as in FIG. 18, the higher-voltage area and the lower-voltage area are not changed, and a battery use indicator Ind based on the operating characteristic of the driving motor M is in the higher-voltage area.

FIG. 19B shows that, when the adjustment according to the embodiment is performed in the condition as in FIG. 18, the lower-voltage area is changed. Accordingly, the battery use indicator Ind based on the operating characteristic of the driving motor M is in the lower-voltage area. The lower-voltage area in FIG. 19B may continuously fluctuate during driving, causing the indicator Ind to alternate between the higher-voltage area and the lower-voltage area.

### SOH-Based Adjustment

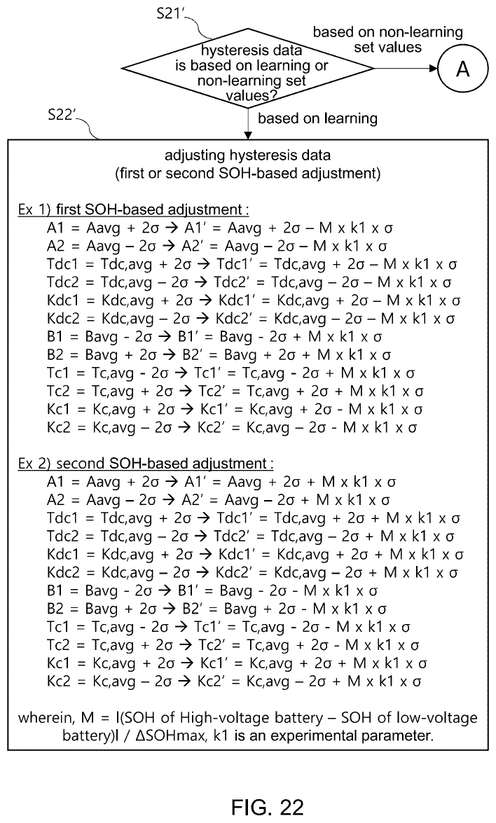

SOH-based adjustment is also conducted differently depending on the determination result of whether the hysteresis data is based on learned data or on non-learned preset values, as shown in step S21′ of FIG. 22.

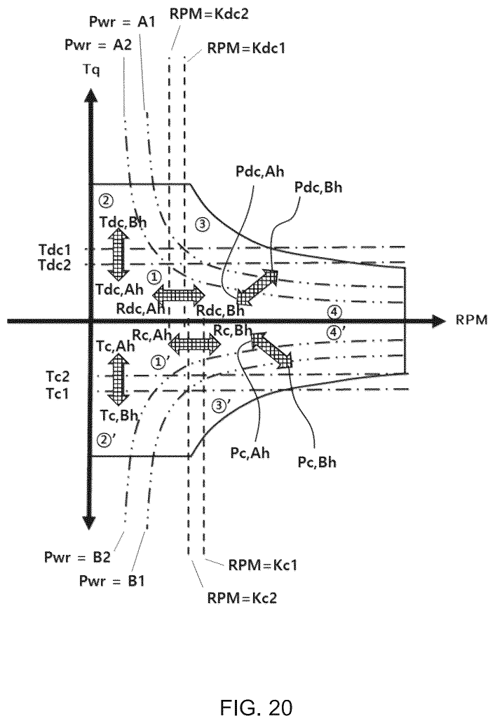

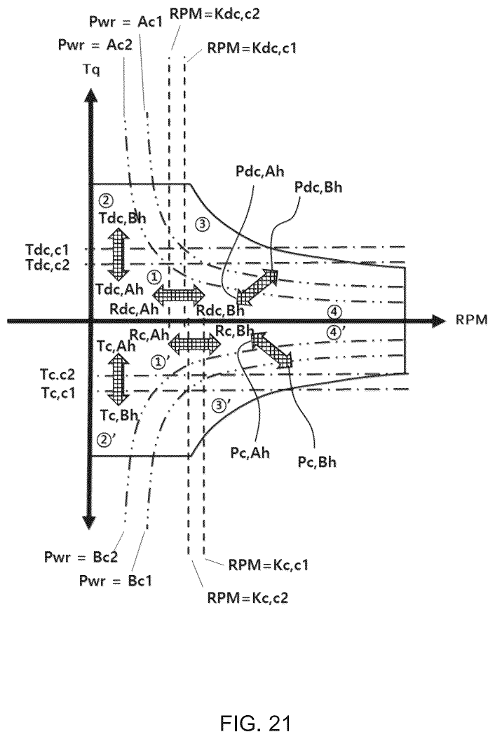

First, step S22′ of FIG. 22 shows an example of a case based on learning, which is described with reference to FIG. 20.

FIG. 20 shows a concept of the adjustment of the reference data in FIG. 8.

Referring to FIG. 20, the first SOH-based adjustment includes the first SOH-based discharging power adjustment Pdc,Ah, the first SOH-based discharging torque adjustment Tdc, Ah, the first SOH-based discharging RPM adjustment Rdc,Ah, the first SOH-based charging power adjustment Pc,Ah, the first SOH-based charging torque adjustment Tc,Ah, and the first SOH-based charging RPM adjustment Rc,Ah. The second SOH-based adjustment includes the second SOH-based discharging power adjustment Pdc,Bh, the second SOH-based discharging torque adjustment Tdc,Bh, the second SOH-based discharging RPM adjustment Rdc,Bh, the second SOH-based charging power adjustment Pc,Bh, the second SOH-based charging torque adjustment Tc,Bh, and the second SOH-based charging RPM adjustment Rc,Bh.

In this embodiment, the first SOH-based adjustment may be determined by Equation 7 below, and the second SOH-based adjustment may be determined by Equation 8 below.

$$[ Mathematical equation 7 ]$$

$$\begin{matrix}A 1 = Aavg + 2 σ \to A 1 ’ = Aavg + 2 σ - M x k 1 x σ \\ A 2 = Aavg - 2 σ \to A 2 ’ = Aavg - 2 σ - M x k 1 x σ \\ Tdc 1 = Tdc , avg + 2 σ \to Tdc 1 ’ = Tdc , avg + 2 σ - M x k 1 x σ \\ Tdc 2 = Tdc , avg - 2 σ \to Tdc 2 ’ = Tdc , avg - 2 σ - M x k 1 x σ \\ Kdc 1 = Kdc , avg + 2 σ \to Kdc 1 ’ = Kdc , avg + 2 σ - M x k 1 x σ \\ Kdc 2 = Kdc , avg - 2 σ \to Kdc 2 ’ = Kdc , avg - 2 σ - M x k 1 x σ \\ B 1 = Bavg - 2 σ \to B 1 ’ = Bavg - 2 σ - M x k 1 x σ \\ B 2 = Bavg + 2 σ \to B 2 ’ = Bavg + 2 σ - M x k 1 x σ \\ Tc 1 = Tc , avg - 2 σ \to Tc 1 ’ = Tc , avg - 2 σ + M x k 1 x σ \\ Tc 2 = Tc , avg + 2 σ \to Tc 2 ’ = Tc , avg + 2 σ + M x k 1 x σ \\ Kc 1 = Kc , avg + 2 σ \to Kc 1 ’ = Kc , avg + 2 σ - M x k 1 x σ \\ Kc 2 = Kc , avg - 2 σ \to Kc 2 ’ = Kc , avg - 2 σ - M x k 1 x σ\end{matrix}$$

$$[ Mathematical equation 8 ]$$

$$\begin{matrix}A 1 = Aavg + 2 σ \to A 1 ’ = Aavg + 2 σ + M x k 1 x σ \\ A 2 = Aavg - 2 σ \to A 2 ’ = Aavg - 2 σ + M x k 1 x σ \\ Tdc 1 = Tdc , avg + 2 σ \to Tdc 1 ’ = Tdc , avg + 2 σ + M x k 1 x σ \\ Tdc 2 = Tdc , avg - 2 σ \to Tdc 2 ’ = Tdc , avg - 2 σ + M x k 1 x σ \\ Kdc 1 = Kdc , avg + 2 σ \to Kdc 1 ’ = Kdc , avg + 2 σ + M x k 1 x σ \\ Kdc 2 = Kdc , avg - 2 σ \to Kdc 2 ’ = Kdc , avg - 2 σ + M x k 1 x σ \\ B 1 = Bavg - 2 σ \to B 1 ’ = Bavg - 2 σ - M x k 1 x σ \\ B 2 = Bavg + 2 σ \to B 2 ’ = Bavg + 2 σ - M x k 1 x σ \\ Tc 1 = Tc , avg - 2 σ \to Tc 1 ’ = Tc , avg - 2 σ - M x k 1 x σ \\ Tc 2 = Tc , avg + 2 σ \to Tc 2 ’ = Tc , avg + 2 σ - M x k 1 x σ \\ Kc 1 = Kc , avg + 2 σ \to Kc 1 ’ = Kc , avg + 2 σ + M x k 1 x σ \\ Kc 2 = Kc , avg - 2 σ \to Kc 2 ’ = Kc , avg - 2 σ + M x k 1 x σ\end{matrix}$$

M is determined by Equation 9 below, in which k1 is a test parameter.

$$[ Mathematical equation 9 ]$$

$$M = \vert ( SOH of high - voltage battery - SOH of low - voltage battery ) \vert / Δ SOH max$$

In other words, M is determined based on a difference between the current SOH of the battery using the higher voltage and the current SOH of the battery using the lower voltage among the first battery MB and the second battery SB.

ΔSOHmax represents a possible difference between the first battery MB and the second battery SB, and this may be determined in advance as the set value. For example, since a theoretically possible difference between the two SOHs is 100%, the difference may be set to 100. However, the difference may be set to a value less than 100 in consideration of a substantial condition.

M is a parameter representing the SOH state of the higher-voltage battery and the lower-voltage battery. As shown in Equations 7 and 8, in this embodiment, the adjustment amount for hysteresis adjustment is determined using the standard deviation σ along with the M parameter and the k1 parameter.

In the first SOH-based adjustment, the discharging reference hysteresis is adjusted to be shifted in a direction that reduces the first discharging operating area (1) by ‘M×k1×σ’, and the charging reference hysteresis is also adjusted to be shifted in a direction that reduces the first charging operating area (1)′ by an absolute value of ‘M×k1×σ’.

Also, in the second SOH-based adjustment, the discharge reference hysteresis is adjusted to be shifted in a direction that expands the first discharging operating area (1) by ‘M×k1×σ’, and the charging reference hysteresis is also adjusted to be shifted in a direction that expands the first charging operating area (1) by an absolute value of ‘M×K1×σ’.

On the other hand, the test parameter k1 may be determined by performing a test driving based on the above-described adjustment and then verifying whether the SOH difference between the first battery MB and the second battery SB substantially decreases. In other words, the k1 may be determined by performing a plurality of test drives while varying k1 and then selecting a smallest difference between the SOHs of two batteries among the test drives.

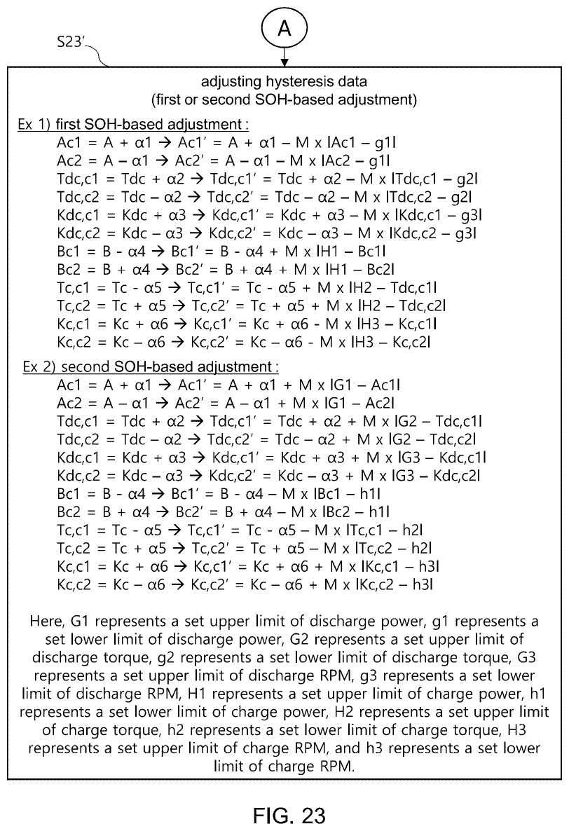

When the hysteresis is not based on learning in step S21′ of FIG. 22, step S23′ of FIG. 23 is performed, which is described below.

In the adjustment of step S23′ in FIG. 23, first discharging power adjustment Pdc,Ah, first discharging torque adjustment Tdc,Ah, first discharging RPM adjustment Rdc,Ah, first charging power adjustment Rc,Ah, first charging torque adjustment Tc,Ah, and first charging RPM adjustment Rc,Ah may be determined by Equation 10 below.

$$[ Mathematical equation 10 ]$$

$$\begin{matrix}Ac 1 = A + α 1 \to Ac 1 ’ = A + α 1 - M x 1 Ac 1 - g 11 \\ Ac 2 = A - α 1 \to Ac 2 ’ = A - α 1 - M x 1 Ac 1 - g 11 \\ Tdc , c 1 = Tdc + α 2 \to Tdc , c 1 ’ = Tdc + α 2 - M x lTdc , c 1 - g 21 \\ Tdc , c 2 = Tdc - α 2 \to Tdc , c 2 ’ = Tdc - α 2 - M x lTdc , c 2 - g 21 \\ Kdc , c 1 = Kdc + α 3 \to Kdc , c 1 ’ = Kdc + α 3 - M x lKdc , c 1 - g 31 \\ Kdc , c 2 = Kdc - α 3 \to Kdc , c 2 ’ = Kdc - α 3 - M x lKdc , c 2 - g 31 \\ Bc 1 = B - α 4 \to Bc 1 ’ = B - α 4 + M x lH 1 - Bc 11 \\ Bc 2 = B + α 4 \to Bc 2 ’ = B + α 4 + M x lH 1 - Bc 21 \\ Tc , c 1 = Tc - α 5 \to Tc , c 1 ’ = Tc - α 5 + M x lH 2 - Tc , c 11 \\ Tc , c 2 = Tc + α 5 \to Tc , c 2 ’ = Tc + α 5 + M x lH 2 - Tc , c 21 \\ Kc , c 1 = Kc + α 6 \to Kc , c 1 ’ = Kc + α 6 - M x lH 3 - Kc , c 11 \\ Kc , c 2 = Kc - α 6 \to Kc , c 2 ’ = Kc - α 6 - M x lH 3 - Kc , c 21\end{matrix}$$

Also, in the adjustment of step S23′ in FIG. 23, second discharging power adjustment Pdc,Bh, second discharging torque adjustment Tdc,Bh, second discharging RPM adjustment Rdc,Bh, second charging power adjustment Pc,Bh, second charging torque adjustment Tc,Bh, and second charging RPM adjustment Rc,Bh may be determined through Equation 11 below.

$$\begin{matrix}[ Mathematical equation 11 ] & \end{matrix}$$

$$\begin{matrix}Ac 1 = A + α 1 \to Ac 1 ’ = A + α 1 - M x 1 Ac 1 - g 11 \\ Ac 2 = A - α 1 \to Ac 2 ’ = A - α 1 - M x 1 Ac 1 - g 11 \\ Tdc , c 1 = Tdc + α 2 \to Tdc , c 1 ’ = Tdc + α 2 - M x lTdc , c 1 - g 21 \\ Tdc , c 2 = Tdc - α 2 \to Tdc , c 2 ’ = Tdc - α 2 + M x lG 2 - Tdc , c 21 \\ Kdc , c 1 = Kdc + α 3 \to Kdc , c 1 ’ = Kdc + α 3 + M x lG 3 - Kdc , c 11 \\ Kdc , c 2 = Kdc - α 3 \to Kdc , c 2 ’ = Kdc - α 3 + M x lG 3 - Kdc , c 21 \\ Bc 1 = B - α 4 \to Bc 1 ’ = B - α 4 - M x lBc 1 - h 11 \\ Bc 2 = B + α 4 \to Bc 2 ’ = B + α 4 - M x lBc 2 - h 11 \\ Tc , c 1 = Tc - α 5 \to Tc , c 1 ’ = Tc - α 5 - M x lTc , c 1 - h 11 \\ Tc , c 2 = Tc + α 5 \to Tc , c 2 ’ = Tc + α 5 - M x lTc , c 2 - h 21 \\ Kc , c 1 = Kc + α 6 \to Kc , c 1 ’ = Kc + α 6 + M x lKc , c 1 - h 31 \\ Kc , c 2 = Kc - α 6 \to Kc , c 2 ’ = Kc - α 6 + M x lKc , c 2 - h 31\end{matrix}$$

G1 represents a set upper limit for discharging power, g1 represents a set lower limit for discharging power, G2 represents a set upper limit for discharging torque, g2 represents a set lower limit for discharging torque, G3 represents a set upper limit for discharging RPM, g3 represents a set lower limit for discharging RPM, H1 represents a set upper limit for charging power, h1 represents a set lower limit for charging power, H2 represents a set upper limit for charging torque, h2 represents a set lower limit for charging torque, H3 represents a set upper limit for charging RPM, and h3 represents a set lower limit for charging RPM, which may be determined as set values.

For example, G1 and g1 may be a maximum power and a minimum power of the driving motor M, respectively.

Similarly, when the hysteresis is adjusted to be shifted, this shifting does not exceed the upper or lower limits in consideration of absolute values of differences between the above-described upper or lower limits and the reference before being adjusted.

For example, when adjusting the equivalent power line ‘Pwr=Ac1,’ a adjustment amount of the shifting is determined by multiplying M that is the SOH parameter to an absolute value of the difference between power Ac1 and g1, so that the adjustment does not exceed the set lower limit of the discharging power even when M has a maximum value of 1.

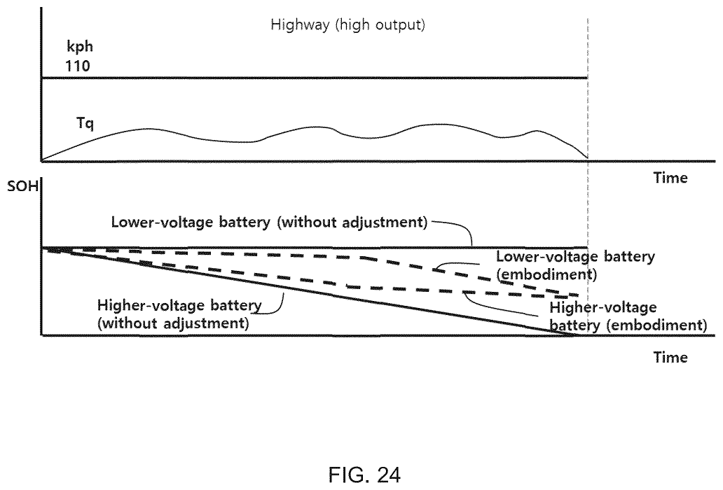

FIG. 24 conceptually shows SOHs of the higher-voltage battery and the lower-voltage battery in a case when the SOH-based adjustment of the above-described reference data is performed and a case when the adjustment is not performed for an assumed condition of driving at a speed of 110 kph on a highway section.

As shown in FIG. 24, when the adjustment of the reference data is not performed, only a higher-voltage battery is used because it is a high-output condition. Accordingly, although the SOH of the higher-voltage battery is significantly reduced after the driving is completed, the lower-voltage battery is not used to maintain the SOH thereof.

On the other hand, when the SOH-based adjustment of the reference data is performed, the lower-voltage discharging area is adjusted to be expanded, and the lower-voltage battery is used. Accordingly, after the driving is completed, the SOHs of both batteries become relatively similar.

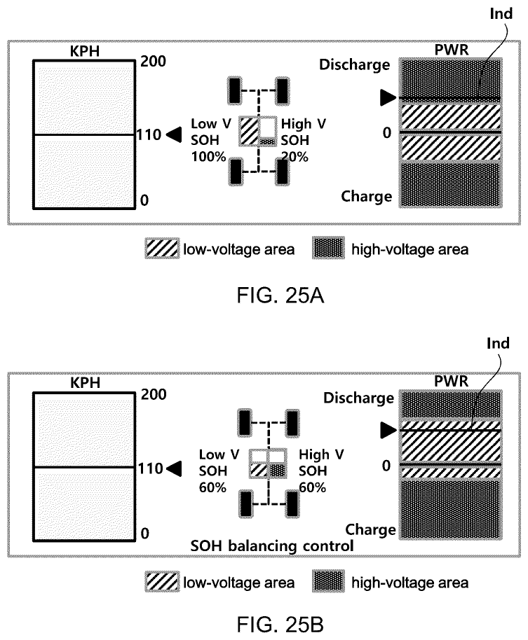

This adjustment of the reference data may be displayed on an instrument cluster in the vehicle, which is illustrated in FIGS. 25A and 25B.

FIG. 25A shows that, when the adjustment is not performed in a condition as in FIG. 24, the higher-voltage area and the lower-voltage area are not changed, and a battery use indicator Ind based on the operating characteristic of the driving motor M is in the higher-voltage area.

FIG. 25B shows that, when the adjustment according to the embodiment is performed in the condition as in FIG. 24, the lower-voltage area is changed, and accordingly, the battery use indicator Ind based on the operating characteristic of the driving motor M is in the lower-voltage area. The lower-voltage area in FIG. 25B may continuously fluctuate during driving, causing the indicator Ind to alternate between the higher-voltage area and the lower-voltage area.

### Soc/Soh-Based Adjustment

SOC/SOH-based adjustment is a method in which both the SOC-based adjustment and the SOH-based adjustment are performed together.

Even in this case, the SOC-based adjustment in mathematical Equations 2 and 3 and the SOH-based adjustment in mathematical Equations 7 and 8 are applied together. The SOC-based adjustment in mathematical Equations 5 and 6 and the SOH-based adjustment in mathematical Equations 10 and 11 are applied together.

In the SOC/SOH-based adjustment, an adjustment amount for the reference data may be determined by an adjustment amount of the SOC-based adjustment (hereinafter, referred to as a first adjustment amount) and an adjustment amount of the SOH-based adjustment (hereinafter, referred to as a second adjustment amount).

The adjustment amount may be determined by addition or multiplication of the first adjustment amount and the second adjustment amount. A weight may be applied differently to the first and second adjustment amounts before the addition or multiplication.

For example, in case of learning-based reference data, the adjustment amount for SOC/SOH-based adjustment can be determined by the sum of the first adjustment amount, ‘T×k×σ’, from Equation 2, and the second adjustment amount, ‘M×k1×σ’, from Equation 7.

Alternatively, the adjustment amount may be determined by applying multiplication to the two adjustment amounts, resulting in T×k×M×k1×σ.

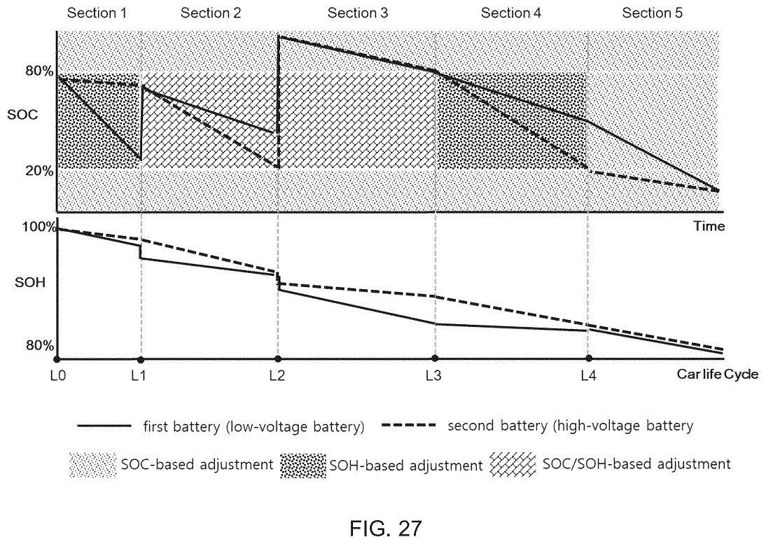

FIG. 27 is a conceptual view illustrating variations of SOCs and SOHs of the dual-batteries for assumed driving conditions according to an embodiment of the present disclosure.

As illustrated, the adjustment mode is determined and performed based on the SOC and SOH of the two batteries.

First, in section 1, the first battery is used, and charging of the first battery is performed as the SOC decreases. At point L0, there is no difference between SOCs of the two batteries, the SOC-based adjustment is not performed, and SOH-based adjustment may be performed.

At point L1, as the charging of the first battery is performed, the SOH decreases, and the SOC/SOH-based adjustment is performed in section 2.

At point L2, both the batteries undergo rapid charging, causing fluctuations in the SOHs. Both the batteries are overcharged, and the SOC-based adjustment is performed in section 3.

The driving condition of section 3 causes a significant difference between the SOHs of the two batteries.

As the difference between the SOHs increases in section 3, the SOH-based adjustment is initiated at point L3 and performed in section 4.

As the over-discharging of the second battery occurs in section 4, the SOC-based adjustment is determined at point L4 and performed in section 5.

When driving according to this embodiment, as shown in FIG. 27, there is no difference between SOCs and between SOHs of the two batteries when driving is completed. In other words, an excellent balancing effect for SOC and SOH of the two batteries may be achieved.

According to the embodiment of the present disclosure, the efficient operating strategy for the dual batteries based on operating points of the driving motor by dividing the area into the plurality of operating areas based on the SOCs and/or SOHs of the dual batteries may be obtained.

Also, according to an embodiment of the present disclosure, the deviation between SOHs and the deviation between SOHs of the dual batteries may be reduced, and accordingly, the durability of each of the dual batteries may be strengthened.

Also, according to an embodiment of the present disclosure, the two batteries may be distinguished in usage by variably controlling the usage switching reference of the dual batteries based on the driving characteristics of the driver, the vehicle condition, and the state of the battery.

Also, according to an embodiment of the present disclosure, since the second high-voltage battery may be added to or separated from the power system of the electric vehicle as necessary in addition to the first high-voltage battery installed in advance on the electric vehicle, the driving distance may be extended.

1. A method for controlling batteries for an electric vehicle, the method comprising:
determining, by a controller, a battery between a first battery and a second battery based on an operating area in which an operating characteristic of a driving motor is disposed among a plurality of operating areas; and
controlling, by the controller, power supply from the determined battery to the driving motor or charging the determined battery by power generated by the driving motor,
wherein the determining the battery between the first battery and the second battery includes:
determining, by the controller, an adjustment mode for reference data that divide the plurality of operating areas based on states of charge (SOCs) and states of health (SOHs) of the first battery and the second battery, and
adjusting, by the controller, the reference data based on the determined adjustment mode.

2. The method of claim 1, wherein the adjustment mode comprises a SOC-based adjustment, a SOH-based adjustment, and a SOC/SOH-based adjustment.

3. The method of claim 2, wherein the determining the adjustment mode comprises at least one of:
determining the SOC-based adjustment as the adjustment mode when an SOC of at least one battery of the first battery and the second battery is deviated from a set SOC range;
determining the SOH-based adjustment as the adjustment mode when both SOCs of the first battery and the second battery are within the set SOC range; and
determining the SOC/SOH-based adjustment as the adjustment mode when both the SOCs of the first battery and the second battery are within the set SOC range, a difference between the SOCs of the first battery and the second battery is less than a set SOC difference, and a difference between SOHs of the first battery and the second battery is deviated from a set SOH range.

4. The method of claim 2, wherein the SOC-based adjustment comprises adjusting the reference data based on the SOCs of the first battery and the second battery.

5. The method of claim 4, wherein the SOC-based adjustment comprises:
a first SOC-based adjustment of adjusting the reference data based on a first mode oriented towards charging a lower-voltage battery or discharging a higher-voltage battery when a first SOC of the lower-voltage battery among the first battery and the second battery is less than a second SOC of the higher-voltage battery among the first battery and the second battery; or
a second SOC-based adjustment of adjusting the reference data based on a second mode oriented towards discharging the lower-voltage battery or charging the higher-voltage battery when the first SOC is greater than the second SOC.

6. The method of claim 5, wherein the first SOC-based adjustment comprises adjusting the reference data to extend a higher-voltage discharging area or a lower-voltage charging area of the plurality of operating areas, and
wherein the second SOC-based adjustment comprises adjusting the reference data to extend a lower-voltage discharging area or a higher-voltage charging area of the plurality of operating areas.

7. The method of claim 6, wherein the reference data includes at least one hysteresis of: power-based hysteresis; torque-based hysteresis; or revolutions per minute (RPM)-based hysteresis, and
wherein the adjusting the reference data comprises adjusting the at least one hysteresis.

8. The method of claim 7, wherein the at least one hysteresis is determined based on an average and a standard deviation obtained based on learning data.

9. The method of claim 8, wherein the adjusting the at least one hysteresis comprises adjusting the at least one hysteresis by an adjustment amount determined based on the standard deviation.

10. The method of claim 9 wherein the adjustment amount is determined based on a difference between the first SOC and the second SOC and the standard deviation.

11. The method of claim 2, wherein the SOH-based adjustment comprises adjusting the reference data based on the SOHs of the first battery and the second battery.

12. The method of claim 11, wherein the SOH-based adjustment comprises:
a first SOH-based adjustment of adjusting the reference data to increase use of a higher-voltage battery among the first battery and the second battery and to decrease use of a lower-voltage battery among the first battery and the second battery when a first SOH of the lower-voltage battery is less than a second SOH of the higher-voltage battery; or
a second SOH-based adjustment of adjusting the reference data to increase the use of the lower-voltage battery and to decrease the use of the higher-voltage battery when the first SOH is greater than the second SOH.

13. The method of claim 12, wherein the first SOH-based adjustment comprises adjusting the reference data to extend a higher-voltage discharging area or a higher-voltage charging area of the plurality of operating areas, and wherein the second SOH-based adjustment comprises adjusting the reference data to extend a lower-voltage discharging area or a lower-voltage charging area of the plurality of operating areas.

14. The method of claim 13, wherein the reference data comprises at least one hysteresis of: power-based hysteresis; torque-based hysteresis; or revolutions per minute (RPM)-based hysteresis, and
wherein the adjusting of the reference data comprises adjusting the at least one hysteresis.

15. The method of claim 14, wherein the at least one hysteresis is determined based on an average and a standard deviation obtained through learning.

16. The method of claim 15, wherein the adjusting of the at least one hysteresis comprises adjusting the at least one hysteresis by an adjustment amount determined based on the standard deviation.

17. The method of claim 16, wherein the adjustment amount is determine based on a difference between the first SOH and the second SOH and the standard deviation.

18. The method of claim 2, wherein the SOC/SOH-based adjustment comprises:
determining a first adjustment amount to change the reference data based on the SOCs of the first battery and the second battery; and
determining a second adjustment amount to change the reference data based on the SOHs of the first battery and the second battery.

19. The method of claim 18, wherein the SOC/SOH-based adjustment further comprises determining a total adjustment amount by addition or multiplication of the first adjustment amount and the second adjustment amount.

20. An electric vehicle comprising:
a plurality of wheels;
a driving motor configured to supply driving force to the plurality of wheels;
a controller configured to control at least one of power supply for the driving motor using a first battery or a second battery or charging the first battery or the second battery by power generated by the driving motor, the controller comprising a non-transitory memory storing computer-readable instructions and at least one processor configured to execute the computer-readable instructions,
wherein the computer-readable instructions, when executed by the at least one processor, causes the controller to:
determine a battery between the first battery and the second battery based on an operating area in which an operating characteristic of the driving motor is disposed among a plurality of operating areas,
control power supply from the determined battery to the driving motor or charging the determined battery by power generated by the driving motor,
determine an adjustment mode for reference data that divide the plurality of operating areas based on states of charge (SOCs) and states of health (SOHs) of the first battery and the second battery, and
adjust the reference data based on the determined adjustment mode.
